(19) United States
(12) Patent Application Publication
(10) Pub. No.: US 2026/0136721 A1
(43) Pub. Date: May 14, 2026

(54) LIGHT-EMITTING UNIT AND METHOD FOR PREPARING SAME, DISPLAY PANEL, AND DISPLAY DEVICE

(71) Applicants: Beijing BOE Technology Development Co., Ltd., Beijing (CN); BOE Technology Group Co., Ltd., Beijing (CN)

(72) Inventors: Tingting ZHOU, Beijing (CN); Xuefei SUN, Beijing (CN); Yingtao WANG, Beijing (CN); Haokun LI, Beijing (CN); Jaegeon YOU, Beijing (CN); Xinxing WANG, Beijing (CN); Jinglu BAI, Beijing (CN)

(73) Assignees: Beijing BOE Technology Development Co., Ltd., Beijing (CN); BOE Technology Group Co., Ltd., Beijing (CN)

(21) Appl. No.: 18/695,944

(22) PCT Filed: Jul. 18, 2023
(86) PCT No.: PCT/CN2023/107919

§ 371 Date: Mar. 27, 2024

(51) Int. Cl. H10H 20/841; H10H 20/01; H10H 20/816; H10H 20/819; H10H 20/857

(52) U.S. Cl. CPC H10H 20/841; H10H 20/017; H10H 20/034; H10H 20/0364; H10H 20/816; H10H 20/819; H10H 20/857

(57) ABSTRACT

Provided is a light-emitting unit. The light-emitting unit includes an epitaxial layer disposed on a side of a substrate, a first trench and a second trench that are in communication with each other and expose the substrate, a first insulative layer disposed on a side, away from the substrate, of the epitaxial layer and covering an inner wall of the first trench, a conductive layer disposed on a side, away from the substrate, of the first insulative layer and extending through the first trench into the second trench, a second insulative layer disposed on a side, away from the substrate, of the conductive layer, and two pads that are respectively electrically connected to the conductive layer and the current spreading layer in the epitaxial layer by the vias running through the insulative layer.

### CROSS-REFERENCE TO RELATED APPLICATION

The application is a U.S. national stage of international application No. PCT/CN2023/107919, filed on Jul. 18, 2023, the content of which is herein incorporated by reference in its entirety.

### TECHNICAL FIELD

The present disclosure relates to the field of display technologies, and in particular, relates to a light-emitting unit and a method for preparing the same, a display panel, and a display device.

### BACKGROUND

Light-emitting diodes (LEDs) are widely used in various types of display products because of their high brightness, low energy consumption, and high color reproduction.

### SUMMARY

Embodiments of the present disclosure provide a light-emitting unit and a method for preparing the same, a display panel, and a display device. The technical solutions are as follows.

According to some embodiments of the present disclosure, a light-emitting unit is provided. The light-emitting unit includes:

a substrate;

an epitaxial layer disposed on a side of the substrate, wherein the epitaxial layer includes a current spreading layer;

at least one first trench and at least one second trench that are in communication with each other and expose the substrate, wherein the at least one first trench runs through the epitaxial layer, and the at least one second trench is disposed between the epitaxial layer and the substrate, an orthographic projection of the at least one second trench on the substrate being overlapped with an orthographic projection of the epitaxial layer on the substrate;

a first insulative layer disposed on a side, away from the substrate, of the epitaxial layer and covering an inner wall of the at least one first trench;

a conductive layer disposed on a side, away from the substrate, of the first insulative layer, wherein the conductive layer extends through the at least one first trench into the at least one second trench and is in contact with the substrate;

a second insulative layer disposed on a side, away from the substrate, of the conductive layer;

a first via running through the second insulative layer and exposing the conductive layer, and a second via successively running through the second insulative layer and the first insulative layer and exposing the current spreading layer; and

a first pad and a second pad that are disposed on a side, away from the substrate, of the second insulative layer and spaced apart from each other, wherein the first pad is electrically connected to the conductive layer through the first via, and the second pad is electrically connected to the current spreading layer through the second via.

In some embodiments, the light-emitting unit further includes:

a sacrificial layer pattern disposed between the substrate and the epitaxial layer, wherein the sacrificial layer pattern has the at least one second trench exposing the substrate.

In some embodiments, the light-emitting unit further includes:

a support layer disposed on the side, away from the substrate, of the epitaxial layer and between the current spreading layer and the first insulative layer, wherein the support layer wraps around a sidewall, close to an edge of the substrate, of the epitaxial layer and is in contact with the substrate;

wherein the at least one first trench successively runs through the support layer and the epitaxial layer, and the first insulative layer is disposed on a side, away from the substrate, of the support layer and covers the inner wall of the at least one first trench.

In some embodiments, a material of the support layer includes an insulative material.

In some embodiments, the second via includes a first sub-via and a second sub-via that are in communication with each other, the first sub-via running through the first insulative layer and exposing the current spreading layer, and the second sub-via running through the second insulative layer; and the second pad includes a conductive electrode and a pad body;

wherein the conductive electrode is disposed within the first sub-via and is electrically connected to the current spreading layer through the first sub-via; and the pad body is disposed on the side, away from the substrate, of the second insulative layer and is electrically connected to the conductive electrode through the second sub-via.

In some embodiments, the conductive electrode and the conductive layer are disposed in a same layer.

In some embodiments, the conductive layer includes a first conductive block and a second conductive block; wherein the first conductive block is filled within the at least one second trench; and the second conductive block is disposed on the side, away from the substrate, of the first insulative layer, filled within the at least one first trench, and electrically connected to the first conductive block through the at least one first trench.

In some embodiments, the light-emitting unit further satisfies any one of the following conditions:

the epitaxial layer includes a first semiconductor layer, a light-emitting layer, and a second semiconductor layer that are disposed between the current-extending layer and the substrate and successively stacked along a direction away from the substrate;

the first pad includes an N-type pad;

the second pad includes a P-type pad;

the substrate includes a sapphire substrate; and

the second insulative layer includes a distributed Bragg reflector.

According to some embodiments of the present disclosure, a method for preparing a light-emitting unit is provided. The method is applied to preparing the light-emitting unit as described above. The method includes:

acquiring a substrate;

successively forming a sacrificial layer and an epitaxial layer on the substrate, wherein the formed epitaxial layer includes a current spreading layer;

forming at least one first trench running through the epitaxial layer and exposing the sacrificial layer;

forming a first insulative layer, wherein the formed first insulative layer is disposed on a side, away from the substrate, of the epitaxial layer and covers an inner wall of the at least one first trench;

forming at least one second trench that is in communication with the at least one first trench by removing at least a portion of the sacrificial layer, such that the substrate is exposed by the at least one first trench and the at least one second trench that are in communication with each other, wherein an orthographic projection of the formed at least one second trench on the substrate is overlapped with an orthographic projection of the epitaxial layer on the substrate;

forming a conductive layer, wherein the formed conductive layer is disposed on a side, away from the substrate, of the first insulative layer, extends through the at least one first trench into the at least one second trench, and is in contact with the substrate;

forming a second insulative layer on a side, away from the substrate, of the conductive layer;

forming a first via running through the second insulative layer and exposing the conductive layer and a second via successively running through the second insulative layer and the first insulative layer and exposing the current spreading layer; and

forming a first pad and a second pad that are spaced apart from each other on a side, away from the substrate, of the second insulative layer, wherein the formed first pad is electrically connected to the conductive layer through the first via, and the formed second pad is electrically connected to the current spreading layer through the second via.

In some embodiments, forming the at least one second trench that is in communication with the at least one first trench by removing at least a portion of the sacrificial layer, includes:

forming the at least one second trench that is in communication with the at least one first trench by removing a portion, disposed between the at least one first trench and the substrate, of the sacrificial layer.

In some embodiments, prior to forming the first insulative layer, the method further includes:

forming a support layer, wherein the formed support layer is disposed on the side, away from the substrate, of the epitaxial layer, wraps around sidewalls, close to an edge of the substrate, of the epitaxial layer and the sacrificial layer, and is in contact with the substrate;

wherein the formed at least one first trench successively runs through the support layer and the epitaxial layer and exposes the sacrificial layer, and the formed first insulative layer is disposed on a side, away from the substrate, of the support layer and covers the inner wall of the at least one first trench.

In some embodiments, forming the at least one second trench that is in communication with the at least one first trench by removing at least a portion of the sacrificial layer includes:

forming the at least one second trench that is in communication with the at least one first trench by removing all of the sacrificial layer.

In some embodiments, removing at least a portion of the sacrificial layer includes:

removing at least a portion of the sacrificial layer by etching the at least a portion of the sacrificial layer using an etching process.

In some embodiments, forming the second via successively running through the second insulative layer and the first insulative layer and exposing the current spreading layer includes:

prior to forming the second insulative layer, forming a first sub-via running through the first insulative layer and exposing the current spreading layer; and

after forming the second insulative layer, acquiring the second via including the first sub-via and a second sub-via by forming the second sub-via running through the second insulative layer and in communication with the first sub-via; and

forming the second pad on the side, away from the substrate, of the second insulative layer includes:

prior to forming the second insulative layer, forming a conductive electrode within the first sub-via, wherein the formed conductive electrode is electrically connected to the current spreading layer through the first sub-via; and

after forming the second insulative layer, acquiring the second pad including the conductive electrode and a pad body by forming the pad body on the side, away from the substrate, of the second insulative layer, wherein the formed pad body is electrically connected to the conductive electrode through the second sub-via.

In some embodiments, forming the conductive electrode within the first sub-via includes:

after forming the conductive layer, forming the conductive electrode within the first sub-via; or

at the same time as forming the conductive layer, forming the conductive electrode within the first sub-via, wherein the conductive electrode and the conductive layer are disposed in a same layer.

In some embodiments, forming the at least one first trench running through the epitaxial layer and exposing the sacrificial layer includes:

forming the at least one first trench running through the epitaxial layer and exposing the sacrificial layer by etching the epitaxial layer using an etching process;

wherein a number of the formed first trenches is positively related to a size of the light-emitting unit required to be formed, and a shape of each of the formed first trenches and arrangement of the formed first trenches match a shape of the light-emitting unit required to be formed.

In some embodiments, forming the conductive layer includes:

forming the conductive layer by filling a conductive material from the side, away from the substrate, of the first insulative layer toward within the at least one first trench and the at least one second trench;

wherein the conductive material includes a transparent conductive material.

In some embodiments, successively forming the sacrificial layer and the epitaxial layer on the substrate includes:

successively forming a sacrificial film layer and an epitaxial film layer on the substrate, wherein the epitaxial film layer includes a current spearing film layer, and a first semiconductor film layer, a light-emitting film layer, and a second semiconductor film layer that are disposed between the current spearing film layer and the substrate and are successively stacked along a direction away from the substrate; and

forming the sacrificial film layer and the epitaxial film layer that are successively stacked by removing portions, close to an edge of the substrate, of the sacrificial film layer and the epitaxial film layer based on a shape of the light-emitting unit required to be formed, wherein the epitaxial layer further includes a first semiconductor layer, a light-emitting layer, and a second semiconductor layer that are disposed between the current spreading layer and the substrate and successively stacked along the direction away from the substrate.

In some embodiments, successively forming the sacrificial film layer and epitaxial film layer on the substrate includes:

growing the sacrificial film layer on the substrate; and

growing the epitaxial film layer on a side, away from the substrate, of the sacrificial film layer.

In some embodiments, removing the portions, close to the edge of the substrate, of the sacrificial film layer and the epitaxial film layer includes:

removing the portions, close to the edge of the substrate, of the sacrificial film layer and the epitaxial film layer by etching the portions, close to the edge of the substrate, of the sacrificial film layer and the epitaxial film layer using an etching process.

According to some embodiments of the present disclosure, a display panel is provided. The display panel includes: a drive backplane, and a plurality of the light-emitting units as described above;

wherein the driving backplane is coupled to the plurality of the light-emitting units and is configured to drive the plurality of the light-emitting units to emit light.

According to some embodiments of the present disclosure, a display device is provided. The display device includes: a power supply assembly and the display panel as described above;

wherein the power supply assembly is coupled to the display panel and is configured to power the display panel.

### BRIEF DESCRIPTION OF DRAWINGS

For clearer descriptions of the technical solutions in the embodiments of the present disclosure, the following briefly introduces the accompanying drawings to be required in the descriptions of the embodiments. Apparently, the accompanying drawings in the following description show merely some embodiments of the present disclosure, and persons of ordinary skills in the art may still derive other drawings from these accompanying drawings without creative efforts.

FIG. 1 is a schematic structural diagram of a light-emitting unit according to some embodiments of the present disclosure;

FIG. 2 is a schematic structural diagram of another light-emitting unit according to some embodiments of the present disclosure;

FIG. 3 is a schematic structural diagram of still another light-emitting unit according to some embodiments of the present disclosure;

FIG. 4 is a schematic structural diagram of yet still another light-emitting unit according to some embodiments of the present disclosure;

FIG. 5 is a flowchart of a method for preparing a light-emitting unit according to some embodiments of the present disclosure;

FIG. 6A is a schematic diagram of preparation of a portion of film layers in a light-emitting unit based on FIG. 1;

FIG. 6B is a schematic diagram of preparation of another portion of film layers in a light-emitting unit based on FIG. 1;

FIG. 6C is a schematic diagram of preparation of still another portion of film layers in a light-emitting unit based on FIG. 1;

FIG. 6D is a schematic diagram of preparation of yet still another portion of film layers in a light-emitting unit based on FIG. 1;

FIG. 6E is a schematic diagram of preparation of yet still another portion of film layers in a light-emitting unit based on FIG. 1;

FIG. 6F is a schematic diagram of preparation of yet still another portion of film layers in a light-emitting unit based on FIG. 1;

FIG. 6G is a schematic diagram of preparation of yet still another portion of film layers in a light-emitting unit based on FIG. 1;

FIG. 6H is a schematic diagram of preparation of yet still another portion of film layers in a light-emitting unit based on FIG. 1;

FIG. 6I is a schematic diagram of preparation of yet still another portion of film layers in a light-emitting unit based on FIG. 1;

FIG. 7A is a schematic diagram of preparation of a portion of film layers in a light-emitting unit based on FIG. 2;

FIG. 7B is a schematic diagram of preparation of another portion of film layers in a light-emitting unit based on FIG. 2;

FIG. 7C is a schematic diagram of preparation of still another portion of film layers in a light-emitting unit based on FIG. 2;

FIG. 7D is a schematic diagram of preparation of yet still another portion of film layers in a light-emitting unit based on FIG. 2;

FIG. 7E is a schematic diagram of preparation of yet still another portion of film layers in a light-emitting unit based on FIG. 2;

FIG. 7F is a schematic diagram of preparation of yet still another portion of film layers in a light-emitting unit based on FIG. 2;

FIG. 7G is a schematic diagram of preparation of yet still another portion of film layers in a light-emitting unit based on FIG. 2;

FIG. 8A is a schematic diagram of preparation of a portion of film layers in a light-emitting unit based on FIG. 3;

FIG. 8B is a schematic diagram of preparation of another portion of film layers in a light-emitting unit based on FIG. 3;

FIG. 8C is a schematic diagram of preparation of still another portion of film layers in a light-emitting unit based on FIG. 3;

FIG. 8D is a schematic diagram of preparation of yet still another portion of film layers in a light-emitting unit based on FIG. 3;

FIG. 8E is a schematic diagram of preparation of yet still another portion of film layers in a light-emitting unit based on FIG. 3;

FIG. 9A is a schematic diagram of preparation of a portion of film layers in a light-emitting unit based on FIG. 4;

FIG. 9B is a schematic diagram of preparation of another portion of film layers in a light-emitting unit based on FIG. 4;

FIG. 10 is a schematic structural diagram of a display panel according to some embodiments of the present disclosure; and

FIG. 11 is a schematic structural diagram of a display device according to some embodiments of the present disclosure.

### DETAILED DESCRIPTION

The present disclosure is described in further detail with reference to the accompanying drawings, to clearly present the objects, technical solutions, and advantages of the present disclosure.

In some practices, an LED usually includes a sapphire substrate, an epitaxial layer disposed on a side of the sapphire substrate, an N-type electrode, and a P-type electrode. Moreover, LEDs are usually categorized into conventional face-up/flip non-vertical LEDs and vertical LEDs. In the non-vertical LED, the N-type electrode and the P-type electrode are disposed on the same side, and the currents tend to flow horizontally, which results in the crowding of the currents and poor heat dissipation capability. In the vertical LED, the N-type electrode and the P-type electrode are disposed on different sides and the current flows vertically, such that the current distribution is uniform, and the heat dissipation ability is better. Moreover, for the vertical LED, the sapphire substrate is removed by laser ablation in the preparation process, and other parts except for the sapphire substrate are moved to other substrates with better heat dissipation ability to ensure better heat dissipation.

However, the laser ablation may damage the epitaxial layer due to stress mismatch, which results in a low yield of the LED.

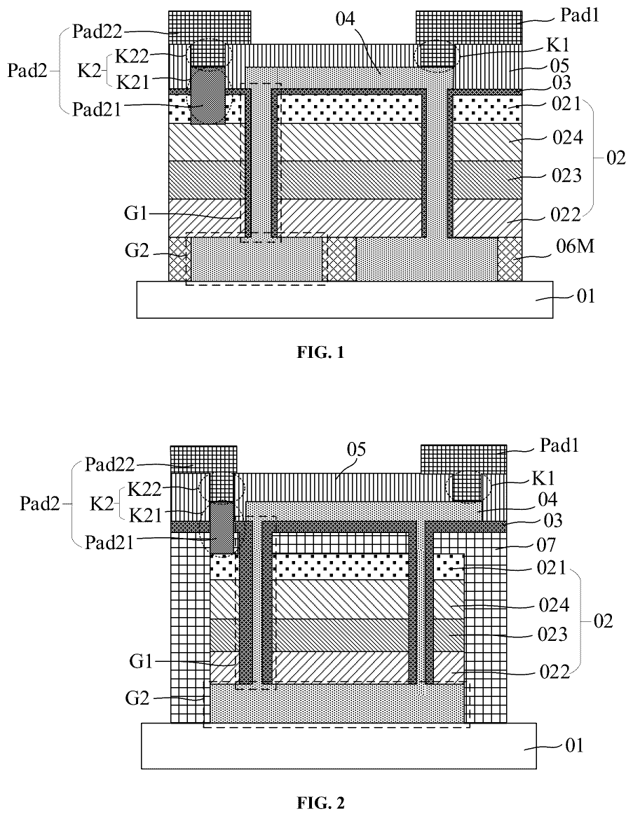

FIG. 1 is a schematic structural diagram of a light-emitting unit according to some embodiments of the present disclosure. The light-emitting unit refers to an LED. As shown in FIG. 1, the light-emitting unit includes:

a substrate 01, an epitaxial layer 02, at least one first trench G1 and at least one second trench G2 that are in communication with each other and expose the substrate 01, a first insulative layer 03, a conductive layer 04, a second insulative layer 05, a first via K1, a second via K2, a first pad Pad1, and a second Pad2.

The epitaxial layer 02 is disposed on a side of the substrate 01, and the epitaxial layer 02 includes a current spreading layer 021.

The at least one first trench G1 runs through the epitaxial layer 02. The at least one second trench G2 is disposed between the epitaxial layer 02 and the substrate 01, and an orthographic projection of the second trench G2 on the substrate 01 is overlapped with an orthographic projection of the epitaxial layer 02 on the substrate 01. That is, the first trench G1 running through the epitaxial layer 02 exposes the second trench G2 in communication with the first trench G1, and the second trench G2 exposes the substrate 01, such that the substrate 01 is exposed by the communicated first trench G1 and second trench G2. Exemplarily, the light-emitting unit shown in FIG. 1 has two first trenches G1 and two second trenches G2 that are in communication in one-to-one correspondence. The two first trenches G1 are spaced apart from each other, and the two second trenches G2 are spaced apart from each other.

The first insulative layer 03 is disposed on a side, away from the substrate 01, of the epitaxial layer 02 and covers an inner wall of the at least one first trench G1.

The conductive layer 04 is disposed on a side, away from the substrate 01, of the first insulative layer 03 and extends through the at least one first trench G1 into the at least one second trench G2 and in contact with the substrate 01. That is, the conductive layer 04 is not only disposed on the side, away from the substrate 01, of the first insulative layer 03, but is also disposed within the first trench G1 and the second trench G2, which are in communication with each other.

This second insulative layer 05 is disposed on a side, away from the substrate 01, of the conductive layer 04.

The first via K1 runs through the second insulative layer 05 and exposes the conductive layer 04, and the second via K2 successively runs through the second insulative layer 05 and the first insulative layer 03 and exposes the current spreading layer 021.

The first pad Pad1 and the second pad Pad2 are disposed on a side, away from the substrate 01, of the second insulative layer 05 and spaced apart from each other. The first pad Pad1 is electrically connected to the conductive layer 04 through the first via K1, and the second pad Pad2 is electrically connected to the current spreading layer 021 through the second via K2. Accordingly, it is known that the first via K1 and the second via K2 are also spaced apart from each other.

In some embodiments, referring to FIG. 1, the epitaxial layer 02 includes, in addition to the current spreading layer 021, a first semiconductor layer 022, a light-emitting layer 023, and a second semiconductor layer 024 that are disposed between the current spreading layer 021 and the substrate 01 and successively stacked along a direction away from the substrate 01.

In this way, the first pad Pad1 is indirectly electrically connected to the first semiconductor layer 022 through the conductive layer 04, and the second pad Pad2 is indirectly electrically connected to the second semiconductor layer 024 through the current spreading layer 021. In addition, both the first pad Pad1 and the second Pad2 are configured to electrically connect to the drive backplane to transmit drive signals (e.g., drive currents) provided by the drive backplane to the first semiconductor layer 022 and the second semiconductor layer 024, respectively, such that the light-emitting layer 023 emits light under the differential pressure provided by the drive signals received by the first semiconductor layer 022 and the second semiconductor layer 024. In conjunction with the structure shown in FIG. 1, the drive current flows along a direction perpendicular to a bearing surface of the substrate 01. The structure of the light-emitting unit described in the embodiments of the present disclosure is similar to that of the non-vertical LED in the related art, and at the same time has the property that the current flows vertically in the vertical LED. Thus, in one aspect, the light-emitting unit described in the embodiments of the present disclosure has the advantages of uniform current distribution and better heat dissipation of the vertical LED; in another aspect, the laser ablation step of the substrate 01 and the step of connecting the electrodes in the vertical LED are eliminated, such that a better yield of the light-emitting unit is ensured, and at the same time, the preparation cost is saved.

Referring to the structure shown in FIG. 1, the first insulative layer 03 is configured to insulate the current spreading layer 021 from the conductive layer 04, such that the interference caused by the interaction between the drive signals transmitted to the first semiconductor layer 022 through the first pad Pad1 and the conductive layer 04 and the drive signals transmitted to the second semiconductor layer 024 through the second pad Pad2 and the current spreading layer 021 is avoided. The second insulative layer 05 is configured to insulate the conductive layer 04 from the pads (including the first pad Pad1 and the second pad Pad2), such that interference caused by the interaction between the signals is avoided.

In summary, some embodiments of the present disclosure provide a light-emitting unit. The light-emitting unit includes the substrate, the epitaxial layer disposed on a side of the substrate, the first trench running through the epitaxial layer, the second trench disposed between the epitaxial layer and the substrate to expose the substrate, wherein the first trench and the second trench are in communication with each other, the first insulative layer disposed on the side, away from the substrate, of the epitaxial layer and covering the inner wall of the first trench, the conductive layer disposed on the side, away from the substrate, of the first insulative layer and extending through the first trench into the second trench, the second insulative layer disposed on the side, away from the substrate, of the conductive layer, and the first pad and the second pad that are respectively electrically connected to the conductive layer and the current spreading layer in the epitaxial layer by the vias running through the insulative layer. In this way, drive currents are reliably supplied by the first pad and the second pad respectively through the conductive layer and the current spreading layer for the two semiconductor layers that are stacked in the epitaxial layer, such that the light-emitting layer sandwiched between the two semiconductor layers reliably emits light. The drive current in the light-emitting unit flows vertically. That is, the light-emitting unit has the advantages of uniform current distribution and better heat dissipation of the vertical LED, and also has the structure of the non-vertical LED, such that the ablation step of the substrate is eliminated, and thus the yield of the light-emitting unit is good.

In some embodiments, referring to FIG. 1, the light-emitting unit documented in some embodiments of the present disclosure further includes a sacrificial layer pattern 06M The sacrificial layer pattern 06M is disposed between the substrate 01 and the epitaxial layer 02, and has the at least one second trench G2 exposing the substrate 01.

In some embodiments, during the preparation process of the light-emitting unit, a sacrificial layer is first formed between the substrate 01 and the epitaxial layer 02, and then the at least one second trench G2 in communication with the at least one first trench G1 is formed by removing a portion of the sacrificial layer disposed between the at least one first trench G1 and the substrate 01. The remaining portion after the portion of the sacrificial layer is removed is referred to as the sacrificial layer pattern 06M.

Optionally, referring to the schematic structural diagram of another light-emitting unit illustrated in FIG. 2, the light-emitting unit documented in some embodiments of the present disclosure further includes a support layer 07.

The support layer 07 is disposed on the side, away from the substrate 01, of the epitaxial layer 02, and is disposed between the current spreading layer 021 and the first insulative layer 03. The support layer 07 wraps around a sidewall, close to an edge of the substrate 01, of the epitaxial layer 02, and is in contact with the substrate 01.

On the basis that the light-emitting unit further includes the support layer 07, referring to FIG. 2, the at least one first trench G1 described above successively runs through the support layer 07 and the epitaxial layer 02, and the first insulative layer 03 is disposed on a side, away from the substrate 01, of the support layer 07, and covers the inner wall of the at least one first trench G1.

Furthermore, based on the embodiments in which the light-emitting unit includes the support layer 07, as shown in FIG. 2, the light-emitting unit includes one second trench G2 simultaneously in communication with both first trenches G1 spaced from each other, and an orthographic projection of the one second trench G2 on the substrate 01 is overlapped the orthographic projection of the epitaxial layer 02 on the substrate 01.

In some embodiments, during the preparation process of the light-emitting unit, the sacrificial layer is first formed between the substrate 01 and the epitaxial layer 02, and then the one second trench G2 is formed by removing all of the sacrificial layer. That is, based on the embodiment shown in FIG. 2, the light-emitting unit does not include the sacrificial layer pattern 06M.

Moreover, for the structure of the embodiment shown in FIG. 2, on the basis of removing the entire sacrificial layer, the structure (e.g., the epitaxial layer 02) after the sacrificial layer is removed during the preparation process is stabilized by providing the support layer 07, which facilitates the subsequent formation of other film layers (e.g., the conductive layer 04) on a side of the epitaxial layer 02. In this way, a good yield is further ensured. Referring to FIG. 1, on the basis of removing only a portion of the sacrificial layer, the remaining sacrificial layer pattern 06M serves as the support layer to stabilize the structure after the sacrificial layer is removed during the preparation process and ensure a better yield without arranging the support layer 07. The description herein is only exemplary, in some embodiments, the light-emitting unit includes both the sacrificial layer pattern 06M shown in FIG. 1 and the support layer 07 shown in FIG. 2 to ensure a better yield, which is not limited herein.

In some embodiments, the material of the support layer 07 includes an insulative material. Accordingly, the support layer 07 is considered as another insulative layer distinct from the first insulative layer 03 and the second insulative layer 05.

In some embodiments, the material of each insulative layer documented in some embodiments of the present disclosure includes at least one of silicon oxide (SiO2), silicon nitride (Si3N4), titanium oxide (TiO2), or aluminum oxide (Al2O3).

In some embodiments, as shown in FIG. 1 and FIG. 2, in the light-emitting unit documented in the embodiments of the present disclosure, the second via K2 includes a first sub-via K21 and a second sub-via K22 that are in communication with each other. The first sub-via K21 runs through the first insulative layer 03 and exposes the current spreading layer 021, and the second sub-via K22 runs through the second insulative layer 05. The second pad Pad2 includes a conductive electrode Pad21 and a pad body Pad22.

The conductive electrode Pad21 is disposed within the first sub-via K21 and is electrically connected to the current spreading layer 021 through the first sub-via K21. The pad body Pad22 is disposed on a side, away from the substrate 01, of the second insulative layer 05 and is electrically connected to the conductive electrode Pad21 through the second sub-via K22.

It should be noted that, as shown in FIG. 2, on the basis that the light-emitting unit also includes the support layer 07, the first sub-via K21 also runs through the support layer 07. That is, the first sub-via K21 successively runs through the first insulative layer 03 and the support layer 07 to reliably expose the current spreading layer 021.

In some embodiments, the material of the conductive electrode Pad21 includes at least one of the metallic materials such as aluminum (Al), molybdenum (Mo), copper (Cu), titanium (Ti), or silver (Ag). For example, the material of the conductive electrode Pad21 includes an alloy consisting of the above metal materials, or a multilayer metal film layer, and the material of the multilayer metal film layer includes the above metal materials. In this way, the conductive effect of the conductive electrode is ensured.

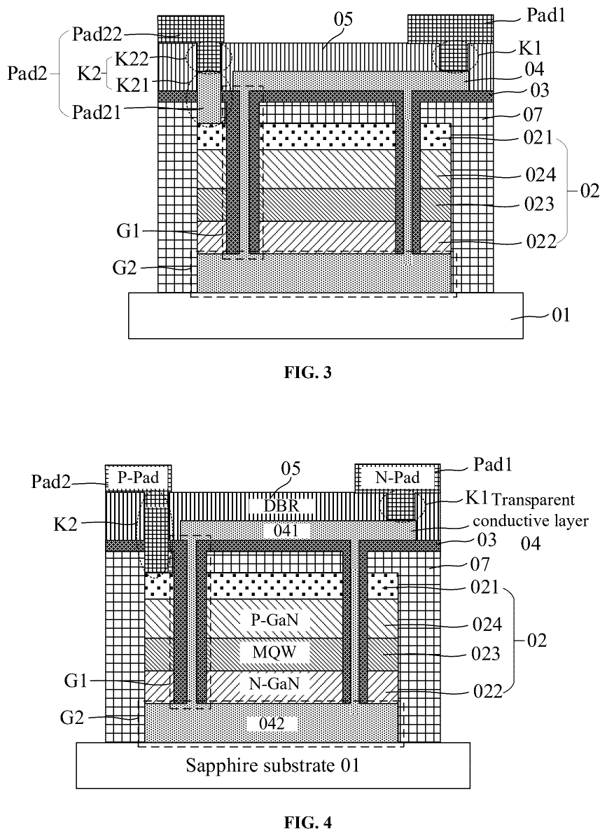

In some embodiments, referring to the schematic structural diagram of yet another light-emitting unit illustrated in FIG. 3, the conductive electrode Pad21 and the conductive layer 04 are disposed in the same layer and represented by the same filling pattern.

It should be noted that the term “disposed in the same layer” refers to a layer structure formed by using the same film-forming process to form a film layer used to form a specific pattern, and then patterning the film layer by a one-patterning process using the same mask. Depending on the specific pattern, the one-patterning process includes multiple exposures, developing or etching processes, and the specific pattern in the formed layer structure is continuous or discontinuous. That is, a plurality of elements, components, structures, and/or portions disposed in the “same layer” are composed of the same material and formed by the same patterning process. In this way, the preparation process and the preparation cost are saved, and the preparation efficiency is improved.

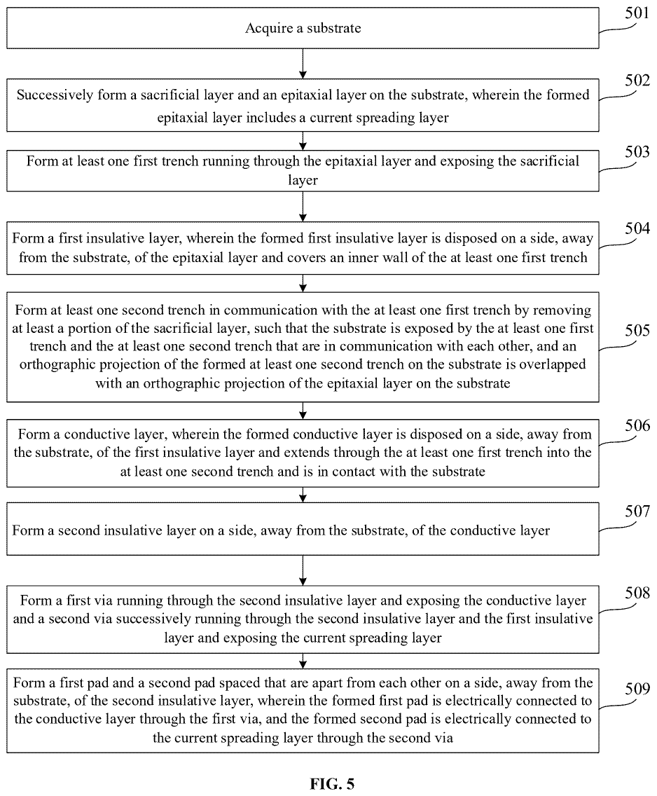

In some embodiments, according to the schematic structural diagram of yet another light-emitting unit shown in FIG. 4, similar to the first pad Pad1, the second pad Pad2 is a whole without including the conductive electrodes Pad21 and the pad body Pad22 electrically connected, and the second pad Pad2 is electrically connected to the current spreading layer 021 directly through the second via K2.

Optionally, referring to the structure shown in FIG. 4, the conductive layer 04 as documented in some embodiments of the present disclosure includes a first conductive block 041 and a second conductive block 042.

The first conductive block 041 is filled within at least one second trench G2. The second conductive block 042 is disposed on the side, away from the substrate 01, of the first insulative layer 03, is filled within the at least one first trench G1, and is electrically connected to the first conductive block 041 through the at least one first trench G1. That is, the conductive layer 04 is divided into a portion disposed within the second trench G2 disposed in a side, close to the substrate 01, of the epitaxial layer 02, and another portion disposed within the epitaxial layer 02 and in a side, away from the substrate 01, of the epitaxial layer 02.

Optionally, one of the first semiconductor layer 022 and the second semiconductor layer 024 documented in some embodiments of the present disclosure is an N-type layer and the other is a P-type layer. One, electrically connected to the N-type layer, of the first pad Pad1 and the second pad Pad2 is a N-type pad (i.e., N-Pad) and the one electrically connected to the P-type layer is a P-type pad (i.e., P-Pad).

Exemplarily, referring to FIG. 4, the first semiconductor layer 022 illustrated in some embodiments of the present disclosure is an N-type layer and the second semiconductor layer 024 is Substitute Specification (Clean) a P-type layer. Accordingly, the first pad Pad1 electrically connected to the first semiconductor layer 022 of the N-type is an N-Pad, and the second pad Pad2 electrically connected to the second semiconductor layer 024 of the P-type is a P-Pad. On the basis that the second pad Pad2 includes the conductive electrode Pad21 and the pad body Pad22 that are electrically connected, the conductive electrode Pad21 refers to a P electrode.

Optionally, the material of the first semiconductor layer 022 of the N-type is gallium nitride (N-GaN) of the N-type, and accordingly, the first semiconductor layer 022 is referred to as an N-GaN layer. The material of the second semiconductor layer 024 of the P-type is gallium nitride (P-GaN) of the P-type, and accordingly, the second semiconductor layer 024 is referred to as a P-GaN layer. The material of the light-emitting layer 023 includes a multiple quantum well (MQW) having a self-luminous effect. Accordingly, the light-emitting layer 023 is referred to as an MQW layer.

Optionally, referring to FIG. 4, the light-emitting unit documented in some embodiments of the present disclosure satisfies any of the following conditions.

First, as documented in the above embodiments, the epitaxial layer 02 includes the first semiconductor layer 022, the light-emitting layer 023, and that second semiconductor layer 024 that are disposed between the current spreading layer 021 and the substrate 01 and stacked successively along the direction away from the substrate 01.

Second, as documented in the above embodiments, the first pad Pad1 includes the N-type pad (i.e., N-Pad), and the second pad Pad2 includes the P-type pad (i.e., P-Pad).

Third, the substrate 01 includes the sapphire substrate. The sapphire substrate has a high light transmittance, and the sapphire is a harder material with more stable chemical properties, such that the light-emitting unit has good light-emitting efficiency and stability.

Fourth, the second insulative layer 05 includes a distributed Bragg reflector (DBR). Accordingly, the second insulative layer 05 is referred to as a DBR layer.

In conjunction with the accompanying drawings, the side, away from the substrate 01, of the second insulative layer 05 is a light-exit surface. In this way, by arranging the second insulative layer 05 that is disposed on the side furthest away from the substrate 01 as the DBR layer, the better reflection effect of the DBR layer is utilized to ensure a better display effect of the light-emitting unit.

Furthermore, in some embodiments, the material of the conductive layer 04 includes a transparent conductive material. Accordingly, the conductive layer 04 is referred to as a transparent conductive layer. On the basis that the second pad Pad2 includes the conductive electrode Pad21 and the pad body Pad22 that are electrically connected, and the conductive electrode Pad21 is disposed on the same layer as the conductive layer 04, the material of the conductive electrode Pad21 is a transparent conductive material that is the same as the conductive layer 04. In this way, the light emitted from the light-emitting layer 023 is ensured to be reliably transmitted, such that the display effect is better.

Optionally, the transparent conductive material includes PSS/PEDOT; conductive plastics made by blending metal or carbon powders with polymers; or 3D printed conductive materials such as polystyrene, graphene, dimethyl formamide, aluminate coupling agent, and isocyanate. It should be noted that the materials documented in the embodiments of the present disclosure are exemplary only.

In some embodiments of the present disclosure, the number of the at least one first trench G1 is positively correlated with the size of the light-emitting unit. The size of the light-emitting unit herein refers to an area of the light-emitting unit. That is, the larger the size of the light-emitting unit, the larger the number of the at least one first trench G1; conversely, the smaller the size of the light-emitting unit, the smaller the number of the at least one first trench G1. For example, one to twenty first trenches G1 are included generally. Exemplary, for a light-emitting unit having a size greater than 0 and less than 10 micrometers (um), one or less than four first trenches G1 are included.

In some embodiments of the present disclosure, the shape of the first trench G1 and the arrangement of the plurality of first trenches G1 match the shape of the light-emitting unit. The term “match” herein indicates that the shapes are the same or similar. For example, assuming that the light-emitting unit is in a rectangular shape, each first trench G1 is in the same rectangular shape. Further, in a scenario where a plurality of (e.g., four) first trenches GI are provided, the shape of a region enclosed by the plurality of first trenches G1 is also in the same rectangular shape. Assuming that the light-emitting unit is in a circular shape, each first trench G1 is in the same circular shape. Further, in a scenario where a plurality of (e.g., four) first trenches G1 are provided, the shape of a region enclosed by the plurality of first trenches G1 is also in the same circular shape.

In summary, some embodiments of the present disclosure provide a light-emitting unit. The light-emitting unit includes the substrate, the epitaxial layer disposed on a side of the substrate, the first trench running through the epitaxial layer, the second trench disposed between the epitaxial layer and the substrate to expose the substrate, wherein the first trench and the second trench are in communication with each other, the first insulative layer disposed on the side, away from the substrate, of the epitaxial layer and covering the inner wall of the first trench, the conductive layer disposed on the side, away from the substrate, of the first insulative layer and extending through the first trench into the second trench, the second insulative layer disposed on the side, away from the substrate, of the conductive layer, and the first pad and the second pad that are respectively electrically connected to the conductive layer and the current spreading layer in the epitaxial layer by the vias running through the insulative layer. In this way, drive currents are reliably supplied by the first pad and the second pad respectively through the conductive layer and the current spreading layer for the two semiconductor layers that are stacked in the epitaxial layer, such that the light-emitting layer sandwiched between the two semiconductor layers reliably emits light. The drive current in the light-emitting unit flows vertically. That is, the light-emitting unit has the advantages of uniform current distribution and better heat dissipation of the vertical LED, and also has the structure of the non-vertical LED, such that the ablation step of the substrate is eliminated, and thus the yield of the light-emitting unit is good.

FIG. 5 is a flowchart of a method for preparing a light-emitting unit according to some embodiments of the present disclosure. The method is applied for preparing a light-emitting unit as shown in any one of FIG. 1 to FIG. 4. As shown in FIG. 5, the method includes the following steps.

In step 501, a substrate is acquired.

In step 502, a sacrificial layer and an epitaxial layer are successively formed on the substrate, wherein the formed epitaxial layer includes a current spreading layer.

In step 503, at least one first trench running through the epitaxial layer and exposing the sacrificial layer is formed.

In step 504, a first insulative layer is formed, wherein the formed first insulative layer is disposed on a side, away from the substrate, of the epitaxial layer and covers an inner wall of the at least one first trench.

In step 505, at least one second trench in communication with the at least one first trench is formed by removing at least a portion of the sacrificial layer, such that the substrate is exposed by the at least one first trench and the at least one second trench that are in communication, and an orthographic projection of the formed at least one second trench on the substrate is overlapped with an orthographic projection of the epitaxial layer on the substrate.

In step 506, a conductive layer is formed, wherein the formed conductive layer is disposed on a side, away from the substrate, of the first insulative layer and extends through the at least one first trench into the at least one second trench and in contact with the substrate.

In step 507, a second insulative layer is formed on a side, away from the substrate, of the conductive layer.

In step 508, a first via running through the second insulative layer and exposing the conductive layer and a second via successively running through the second insulative layer and the first insulative layer and exposing the current spreading layer are formed.

In step 509, a first pad and a second pad spaced that are apart from each other are formed on a side, away from the substrate, of the second insulative layer, wherein the formed first pad is electrically connected to the conductive layer through the first via, and the formed second pad is electrically connected to the current spreading layer through the second via.

Optionally, the preparation method is described hereinafter by using the light-emitting unit illustrated in FIG. 1 to FIG. 4 as an example:

(1) For the light-emitting unit of the structure shown in FIG. 1, the preparation method is as follows.

In step A1, a substrate is acquired.

Optionally, as documented in the above embodiments, the acquired substrate 01 includes a sapphire substrate.

In step A2, a sacrificial film layer and an epitaxial film layer are successively formed on the substrate.

In some embodiments of the present disclosure, the sacrificial film layer is first grown on the acquired substrate, and then the epitaxial film layer is formed on a side, away from the substrate, of the sacrificial film layer.

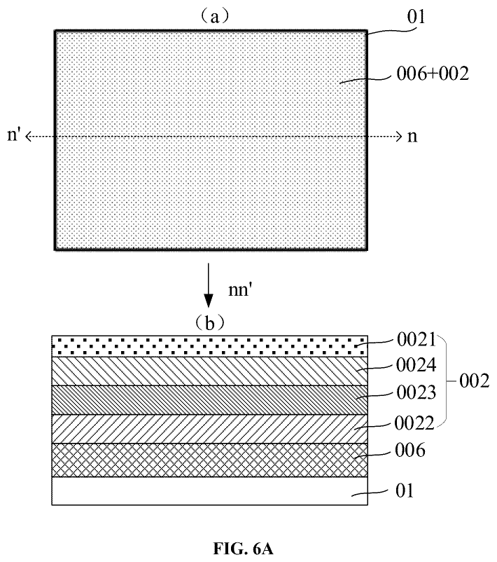

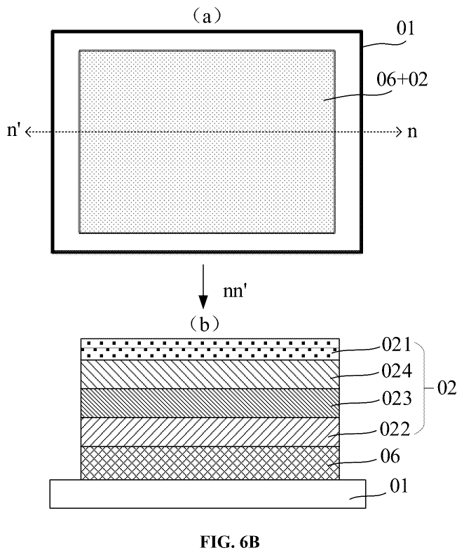

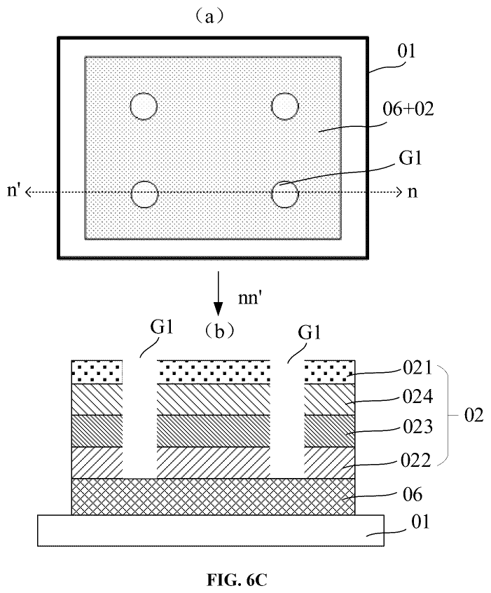

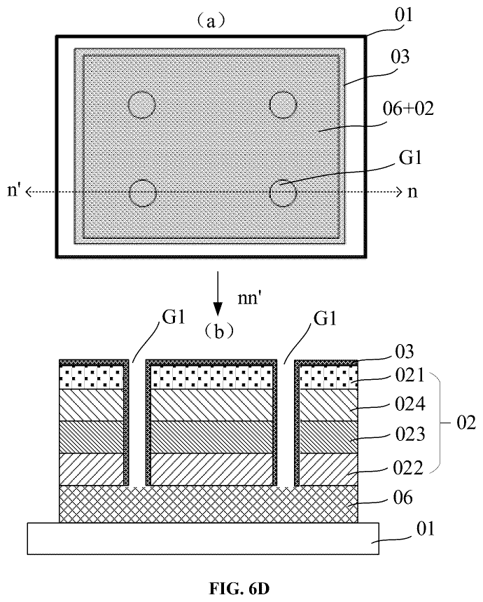

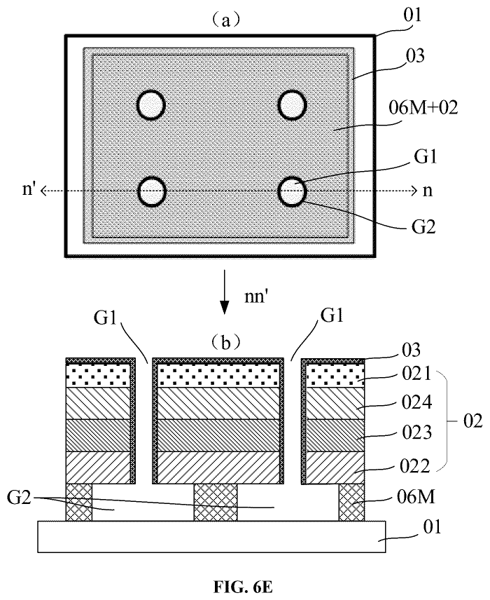

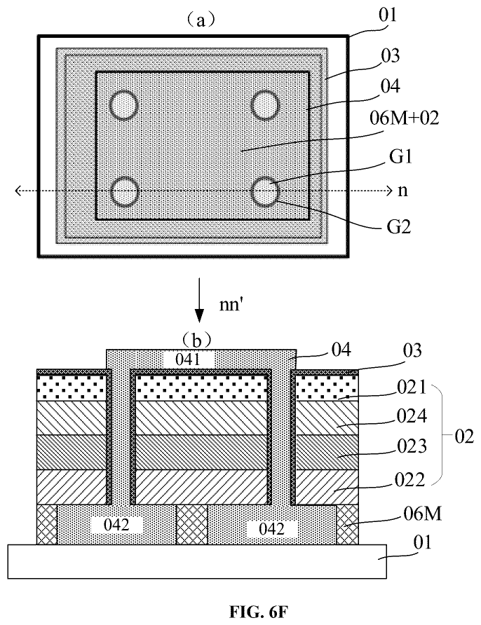

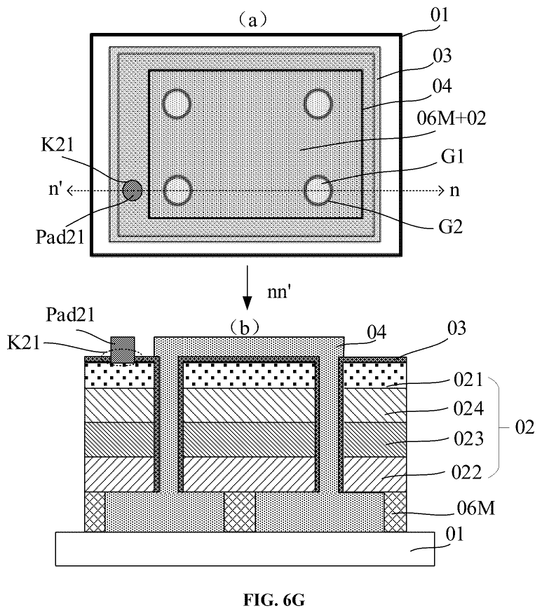

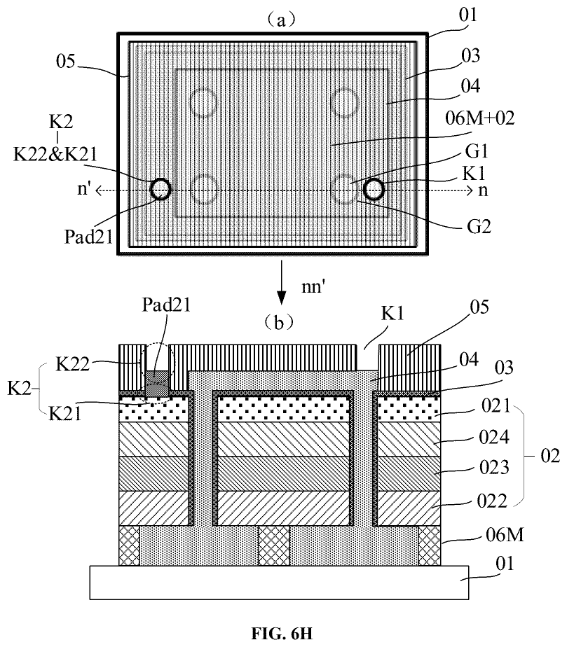

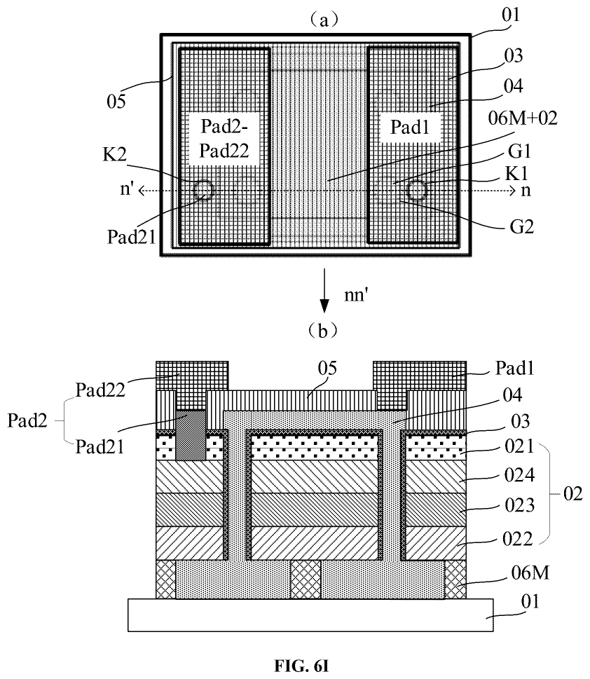

Exemplarily, FIG. 6A is a schematic structural diagram of acquiring the substrate 01 and successively forming the sacrificial film layer 006 and the epitaxial layer 002 on the substrate 01. FIG. 6A further illustrates a top view (see FIG. a) and a section view of the top view in a direction nn′ (see FIG. b). The accompanying drawings illustrated by the following embodiments are similar and are not further described.

Referring to FIG. 6A, the formed epitaxial film layer 002 includes a current spreading film layer 0021, and a first semiconductor film layer 0022, a light-emitting film layer 0023, and a second semiconductor film layer 0024 that are disposed between the current spreading film layer 0021 and the substrate 01 and stacked successively along a direction away from the substrate 01. An orthographic projection of the formed epitaxial film layer 002 on the substrate 01 is overlapped with an orthographic projection of the sacrificial film layer 006 on the substrate 01. The respective edges of the epitaxial film layer 002, the respective edges of the sacrificial film layer 006, and the respective edges of the substrate 01 coincide.

In step A3, based on the shape of the light-emitting unit required to be formed, the sacrificial film layer and the epitaxial film layer that are successively stacked are formed by removing portions, close to an edge of the substrate, of the sacrificial film layer and the epitaxial film layer.

In some embodiments of the present disclosure, in conjunction with FIG. 6A, the portions, close to the edge of the substrate 01, of the sacrificial film layer 006 and the epitaxial film layer 002 are removed by etching the portions using an etching process, such that the sacrificial layer and the epitaxial layer successively stacked are formed.

Exemplarily, FIG. 6B illustrates a schematic structural diagram of the formed successively stacked sacrificial layer 06 and epitaxial layer 02 after the portions, close to the edge of the substrate, of the sacrificial film layer 006 and the epitaxial film layer 002 are removed, including a top view a and a section view b. In conjunction with FIG. 6A and FIG. 6B, on the basis that the formed epitaxial film layer 002 includes the first semiconductor film layer 0022, the light-emitting film layer 0023, the second semiconductor film layer 0024, and the current spreading film layer 0021 that are successively stacked, the formed epitaxial layer 02 includes, in addition to the current spreading layer 021, a first semiconductor layer 022, a light-emitting layer 023, and a second semiconductor layer 024 that are disposed between the current spreading layer 021 and the substrate 01 and successively stacked along the direction away from the substrate 01. Because the sacrificial layer 06 and the epitaxial layer 02 are acquired by removing the edge portions of the sacrificial film layer 006 and the epitaxial film layer 002, in conjunction with FIG. 6B, an orthographic projection of the formed sacrificial layer 06 on the substrate 01 and an orthographic projection of the epitaxial layer 02 on the substrate 01 are overlapped and are surrounded by the substrate 01. This step is referred to as the step etching for defining pixels.

In step A4, at least one first trench running through the epitaxial layer and exposing the sacrificial layer is formed.

In some embodiments of the present disclosure, in conjunction with FIG. 6B, the at least one first trench G1 that runs through the epitaxial layer 02 and exposes the sacrificial layer 06 is formed by etching the epitaxial layer 02 using an etching process. Moreover, the number of formed first trenches G1 is positively correlated to the size of the light-emitting unit required to be formed, and the shape of the formed first trench G1 and the arrangement of the first trenches G1 match the shape of the light-emitting unit required to be formed. That is, the first trench G1 is arranged based on the size and shape of the light-emitting unit.

Exemplarily, FIG. 6C illustrates a schematic structural diagram of forming the first trench G1 that runs through the epitaxial layer 02 and exposes the sacrificial layer 06, including a top view a and a section view b. Referring to FIG. 6C, four first trenches G1 are formed, each of the first trenches G1 is in a circular shape, and a region enclosed by the four first trenches G1 is in a rectangular shape. Moreover, the four first trenches G1 are evenly distributed. The description herein is only exemplary.

In step A5, a first insulative layer is formed.

In some embodiments of the present disclosure, in conjunction with FIG. 6C, the first insulative layer disposed on a side, away from the substrate 01, of the epitaxial layer 02 and covering an inner wall of the at least one first trench G1 is formed by using a patterning process, such that a short circuit does not occur between the first semiconductor layer 022 and the second semiconductor layer 024.

Exemplarily, FIG. 6D illustrates a schematic structural diagram of the formed first insulative layer 03, including a top view a and a section view b.

In step A6, at least one second trench in communication with the at least one first trench is formed by removing a portion, disposed between the at least one first trench and the substrate, of the sacrificial layer.

In some embodiments of the present disclosure, in conjunction with FIG. 6D, the portion, disposed between the at least one first trench G1 and the substrate 01, of the sacrificial layer 06 are removed by etching the at least a portion of the sacrificial layer 06 using an etching process. This step is referred to as sacrificial layer etching.

Exemplarily, FIG. 6E illustrates a schematic structural diagram of the second trench G2 formed by removing a portion of the sacrificial layer 06, including a top view a and a section view b. In conjunction with FIG. 6D and FIG. 6E, because four first trenches G1 are formed, four second trenches G2 that are in corresponding one-to-one communication with the four first trenches G1 are accordingly formed. Each communicated first trench G1 and second trench G2 both expose the substrate 01, and an orthographic projection of each of the second trenches G2 on the substrate 01 is overlapped with the orthographic projection of the epitaxial layer 02 (the first semiconductor layer 022 thereof herein) on the substrate 01.

Furthermore, in conjunction with the embodiments documented above, the remaining sacrificial layer 06 is referred to as the sacrificial layer pattern 06 M. Only a portion of the sacrificial layer 06 is removed, such that the remaining sacrificial layer pattern 06 M serves as a support layer to prevent other portions of the sacrificial layer 06 from collapsing after removal of the sacrificial layer 06, and thus the prepared light-emitting unit is ensured to have a better yield.

In step A7, a conductive layer is formed.

In some embodiments of the present disclosure, in conjunction with FIG. 6E, the conductive layer is formed by filling a conductive material from a side, away from the substrate 01, of the first insulative layer 03 toward within the at least one first trench G1 and the at least one second trench G2. The conductive material includes a transparent conductive material. For the type of the transparent conductive material, reference is made to the structure-side embodiments described above, which is not repeated herein.

Exemplarily, FIG. 6F illustrates a schematic structural diagram of the formed conductive layer, including a top view a and a section view b. Referring to FIG. 6F, the formed conductive layer 04 is disposed on the side, away from the substrate 01, of the first insulative layer 03 and extends through the at least one first trench G1 into the at least one second trench G2 and in contact with the substrate 01. That is, referring to the structure-side embodiments, the formed conductive layer 04 includes a first conductive block 041 and a second conductive block 042.

The first conductive block 041 is filled within the second trench G2. The second conductive block 042 is disposed on the side, away from the substrate 01, of the first insulative layer 03, is filled in the first trench G1, and is electrically connected to the first conductive block 041 through the first trench G1, such that the conductive effect is good.

In step A8, a first sub-via running through the first insulative layer and exposing the current spreading layer is formed.

Optionally, in conjunction with FIG. 6F, the first sub-via running through the first insulative layer and exposing the current spreading layer 021 is formed by etching the first insulative layer 03 using an etching process. Alternatively, this first sub-via is acquired by opening directly by a mask plate while forming the first insulative layer 03 by using the patterning process.

Exemplarily, FIG. 6G illustrates a schematic structural diagram of the formed first sub-via K21, including a top view a and a section view b. Based on the different processes, in some embodiments, the first insulative layer 03 with the sub-via K21 is formed directly prior to forming the second trench G2, i.e., in step A5; or, the first sub-via K21 is formed after forming the conductive layer 04, i.e. after step A7.

In step A9, a conductive electrode is formed within the first sub-via.

Optionally, referring to FIG. 6G, the conductive electrode Pad21 formed within the first sub-via K21 is shown. The conductive electrode Pad21 is electrically connected to the current spreading layer 021 through the first sub-via K21. For the structure shown in FIG. 1 in which the conductive electrode Pad21 and the conductive layer 04 are disposed in different layers, the conductive electrode Pad21 is formed after the conductive layer 04 is formed, as documented in the embodiments.

Optionally, the conductive electrode Pad21 is a P electrode, as documented in the structure-side embodiments described above. Accordingly, step A9 is referred to as a preparation step for the P electrode. For the material of the prepared P electrode, reference is made to the structure-side embodiments described above, which is not repeated herein.

In step A10, a second insulative layer is formed on a side, away from the substrate, of the conductive layer.

Exemplarily, FIG. 6H illustrates a schematic structural diagram of the formed second insulative layer 05, including a top view a and a section view b. Optionally, the second insulative layer 05 is a DBR layer, as documented in the above embodiments.

In step A11, a second via including the first sub-via and a second sub-via is acquired by forming a first via running through the second insulative layer and exposing the electrically conductive layer and the second sub-via running through the second insulative layer and in communication with the first sub-via.

Exemplarily, referring to FIG. 6H, the formed first via K1 and the second sub-via K22 are shown. Optionally, the vias are acquired by etching the insulative layer using an etching process.

In step A12, a first pad is formed on a side, away from the substrate, of the second insulative layer, and a second pad including a pad body and the conductive electrode is acquired by forming a pad body on the side, away from the substrate, of the second insulative layer.

Exemplarily, FIG. 6I illustrates a schematic structural diagram of the formed first pad Pad1 and pad body Pad22, including a top view a and a section view b.

Referring to FIG. 61, the formed first pad Pad1 is electrically connected to the conductive layer 04 through the first via K1, the formed pad body Pad22 is electrically connected to the conductive electrode Pad21 through the second sub-via K22, and the second pad Pad2 including the conductive electrode Pad21 and the pad body Pad22 is acquired. That is, the first pad Pad1 is prepared last, and the first pad Pad1 is electrically connected to the conductive layer 04 through the first via-hole K1, such that a drive signal is transmitted to the first semiconductor layer 022 through the conductive layer 04 by the first pad Pad1, and the second pad Pad2 spaced apart from the first pad Pad1 is prepared and the second pad Pad2 is electrically connected to the current spreading layer 021, such that a drive signal is transmitted to the first semiconductor layer 022 through the current spreading layer 021 by the second pad Pad2. In this way, the light-emitting layer 023 disposed between the first semiconductor layer 022 and the second semiconductor layer 024 reliably emits light.

Optionally, as documented in the structure-side embodiments described above, the first pad Pad1 is an N-Pad and the second pad Pad2 is a P-Pad. Step A12 is referred to as a preparation step for the N-Pad and the P-Pad.

(2) For the light-emitting unit shown in FIG. 2, the preparation method is as follows.

In step B1, a substrate is acquired.

Optionally, for the content of step B1, reference is made to step A1 as described above, which is not repeated herein.

In step B2, a sacrificial film layer and an epitaxial film layer are successively formed on the substrate.

Optionally, for the content of step B2, reference is made to step A2 as described above, which is not repeated herein.

In step B3, based on the shape of the light-emitting unit required to be formed, the sacrificial layer and the epitaxial layer that are successively stacked are formed by removing portions, close to an edge of the substrate, of the sacrificial film layer and the epitaxial film layer.

Optionally, for the content of step B3, reference is made to step A3 as described above, which is not repeated herein.

In step B4, a support layer, and at least one first trench successively running through the support layer and the epitaxial layer and exposing the sacrificial layer are formed.

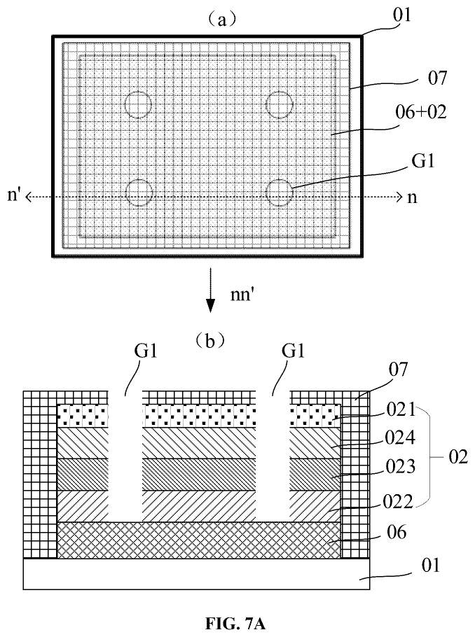

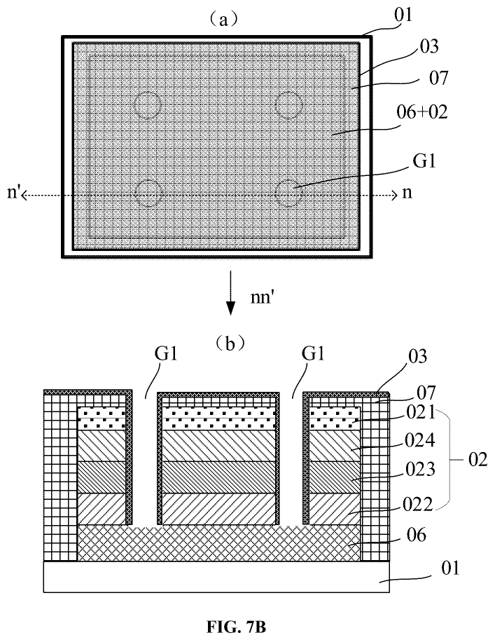

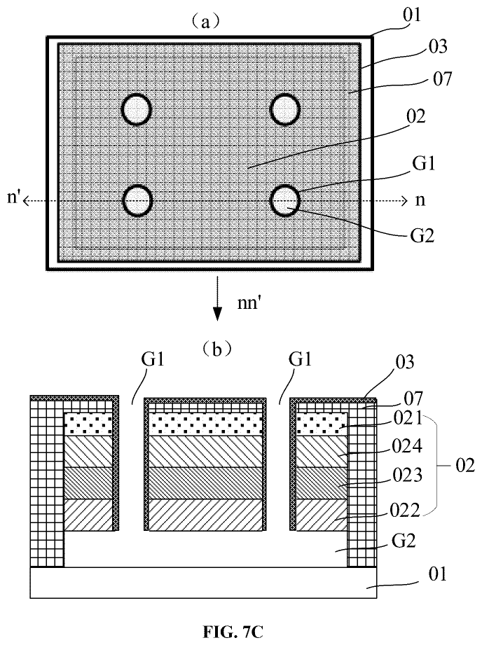

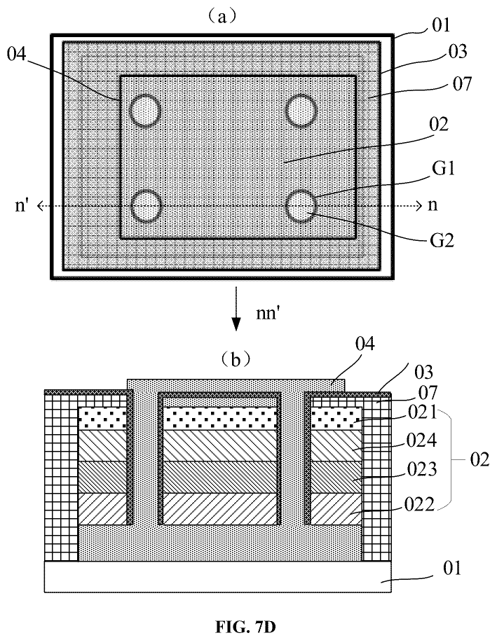

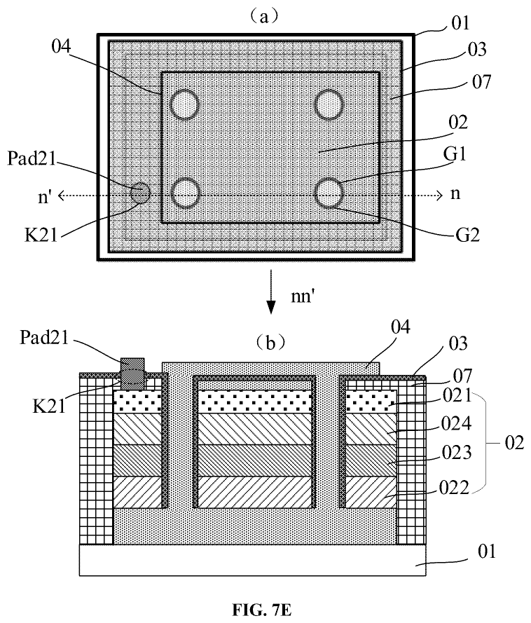

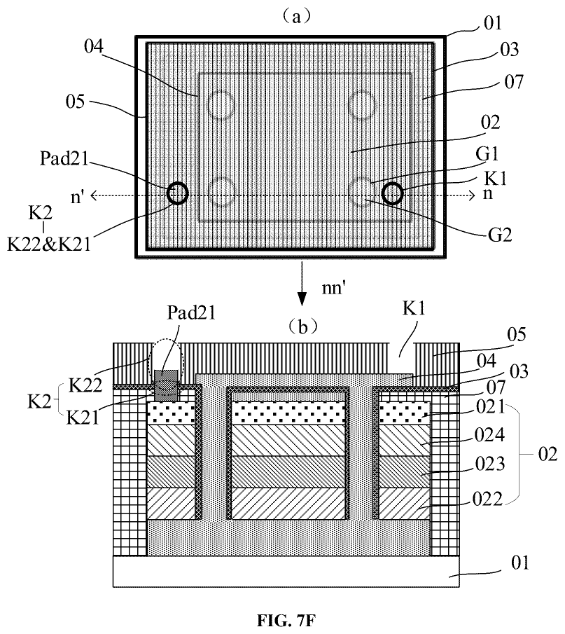

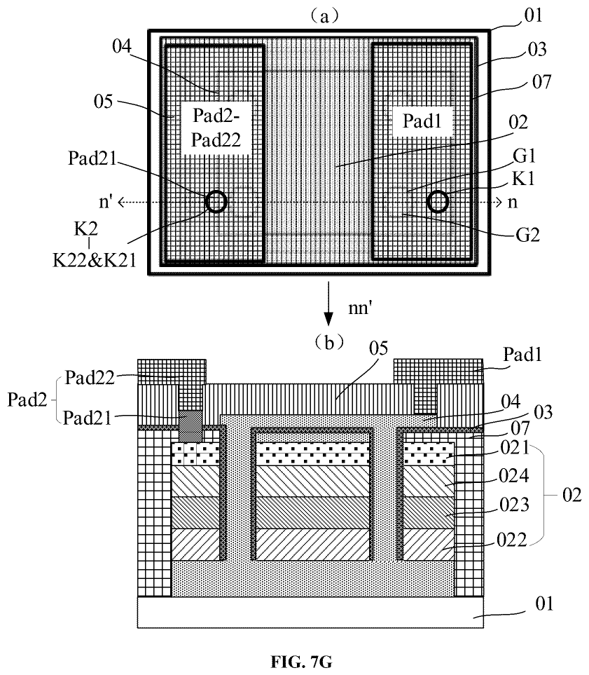

Exemplarily, FIG. 7A illustrates a schematic structural diagram of the formed support layer 07 and first trench G1, including a top view a and a section view b. Referring to FIG. 7A, the formed support layer 07 is disposed on a side, away from the substrate 01, of the epitaxial layer 02, and wraps around sidewalls, close to the edge of the substrate 01, of the epitaxial layer 02 and the sacrificial layer 06 and is in contact with the substrate 01.

In some embodiments, referring to step A4 described above, the first trench G1 running through the epitaxial layer 02 is formed first, and then the support layer 07 is formed at a location shown in FIG. 7A. Alternatively, in some embodiments, after the epitaxial layer 02 and the support layer 07 are formed, the first trench G1 successively running through the epitaxial layer 02 and the support layer 07 is formed by etching the epitaxial layer 02 and the support layer 07 together, accordingly the support layer 07 with the structure shown in FIG. 7A is acquired.

In some embodiments, the material of the formed support layer 07 includes an insulative material, as documented in the structure-side embodiments described above. The support layer 07 serves as a support, such that the subsequent preparation process is performed reliably.

In step B5, a first insulative layer is formed.

Optionally, for the content of step B5, reference is made to step A5 as described above, which is not repeated herein.

Exemplarily, FIG. 7B illustrates a schematic structural diagram of the formed first insulative layer 03, including a top view a and a section view b. Referring to FIG. 7B, in a scenario where the support layer 07 is formed, the formed first insulative layer 03 is disposed on a side, away from the substrate 01, of the support layer 07 and covers an inner wall of at least one of the first trenches G1.

In some embodiments, the first insulative layer 03 and the support layer 07 are formed synchronously and in a one-piece structure because the material of the support layer 07 also includes the insulative material. It should be noted that in this scenario, the first trench G1 running through the epitaxial layer 02 is formed first, and then the first insulative layer 03 and the support layer 07 in a one-piece structure are formed at the location shown in FIG. 7B.

In step B6, one second trench in communication with the at least one first trench is formed by removing all of the sacrificial layer.

Optionally, for the content of step B6, reference is made to step A6 as described above, which is not repeated herein.

Exemplarily, FIG. 7C illustrates a schematic structural diagram the one second trench G2 formed after all of the sacrificial layer 06 is removed, including a top view a and a section view b. Referring to FIG. 7C, the formed one second trench G2 is in communication with each of the first trenches G1 and exposes the substrate 01 at the same time.

Although all of the sacrificial layer 06 is removed in the embodiments, the structure after the sacrificial layer 06 is removed is still stable because the support layer 07 is pre-formed. In other words, because of the presence of the support layer 07, it is possible to remove all of the sacrificial layer 06 and form a light-emitting unit without the sacrificial layer or the sacrificial layer pattern. Referring to FIG. 6I, in a scenario where only part of the sacrificial layer 06 is removed, there is no need to additionally provide the support layer 07 because the remaining sacrificial layer pattern 06M provides the same support. In some embodiments, while only part of the sacrificial layer 06 is removed, it is also possible to additionally provide the support layer 07 to ensure a better stabilizing effect.

In step B7, a conductive layer is formed.

Optionally, for the content of step B7, reference is made to step A7 as described above, which is not repeated herein.

Exemplarily, FIG. 7D illustrates a schematic structural diagram of the formed conductive layer 04, including a top view a and a section view b.

In step B8, a first sub-via running through the first insulative layer and the support layer and exposing the current spreading layer is formed.

It should be noted that in the embodiments, the support layer 07 is also formed between the first insulative layer 03 and the current spreading layer 021. Therefore, in conjunction with FIG. 7D, the first sub-via running through the first insulative layer 03 and the support layer 07 and exposing the current spreading layer 021 is formed by etching the first insulative layer 03 and the support layer 07.

Exemplarily, FIG. 7E illustrates a schematic structural diagram of the formed first sub-via K21, including a top view a and a section view b. It should be noted that for the sequence of steps for forming the first sub-via K21 in the embodiments, reference is made to step A8 described above, which is not repeated herein.

In step B9, a conductive electrode is formed within the first sub-via.

Optionally, for the content of step B9, reference is made to step A9 described above, which is not repeated herein. Step B9 is referred to as a preparation step for the P electrode.

Exemplarily, referring to FIG. 7E which illustrates the formed conductive electrode Pad21, in the embodiments, the conductive electrode Pad21 and the conductive layer 04 are disposed in different layers, and are formed at different stages.

In step B10, a second insulative layer is formed on a side, away from the substrate, of the conductive layer.

Optionally, for the content of step B10, reference is made to step A10 as described above, which is not repeated herein.

Exemplarily, FIG. 7F illustrates a schematic structural diagram of the formed second insulative layer 05, including a top view a and a section view b.

In step B11, a first via running through the second insulative layer and exposing the conductive layer is formed, and a second sub-via including the first sub-via and a second sub-via is acquired by forming the second sub-via that runs through the second insulative layer and is in communication with the first sub-via.

Optionally, for the content of step B11, reference is made to step A11 as described above, which is not repeated herein.

Exemplarily, referring to FIG. 7F, the formed first via K1 and the formed second sub-via K22 are shown.

In step B12, a first pad is formed on a side, away from the substrate, of the second insulative layer, and a second pad including a pad body and the conductive electrode is acquired by forming the pad body on the side, away from the substrate, of the second insulative layer.

Optionally, for the content of step B12, reference is made to step A12 as described above, which is not repeated herein. Step B12 is referred to as a preparation step for the N-Pad and the P-Pad.

Exemplarily, FIG. 7G illustrates a schematic structural diagram of the formed first pad Pad1 and the formed pad body Pad22, including a top view a and a section view b.

(3) For the light-emitting unit shown in FIG. 3, the preparation method is as follows.

In step C1, a substrate is acquired.

Optionally, for the content of step C1, reference is made to step A1 described above, which is not repeated herein.

In step C2, a sacrificial film layer and an epitaxial film layer are successively formed on the substrate.

Optionally, for the content of step C2, reference is made to step A2 described above, which is not repeated herein.

In step C3, based on the shape of the light-emitting unit required to be formed, the sacrificial layer and the epitaxial layer that are successively stacked are formed by removing portions, close to an edge of the substrate, of the sacrificial film layer and the epitaxial film layer.

Optionally, for the content of step C3, reference is made to step A3 described above, which is not repeated herein.

In step C4, a support layer and at least one first trench that runs successively through the support layer and the epitaxial layer and exposes the sacrificial layer are formed.

Optionally, for the formation of the support layer, reference is made to step B4 described above, which is not repeated herein.

In step C5, a first insulative layer, and a first sub-via that successively runs through the first insulative layer and the support layer and exposes the current spreading layer are formed.

Optionally, for the formation of the first insulative layer, reference is made to step A5 described above, which is not repeated herein. For the formation of the first sub-via, reference is made to step B8 described above, which is not repeated herein. That is, in the embodiments, the first sub-via is formed at the same time as the first insulative layer is formed, as described above.

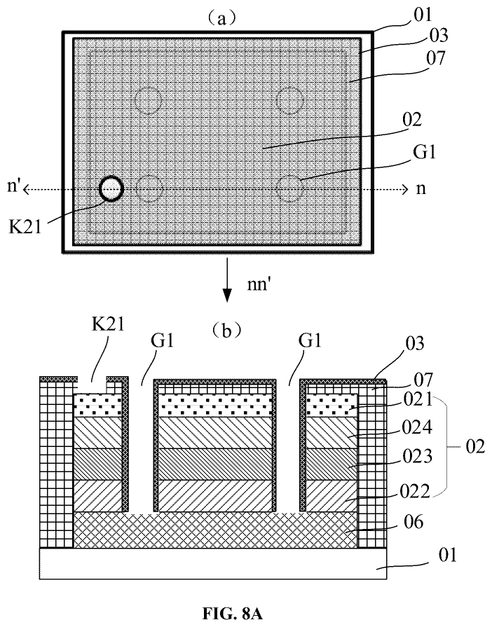

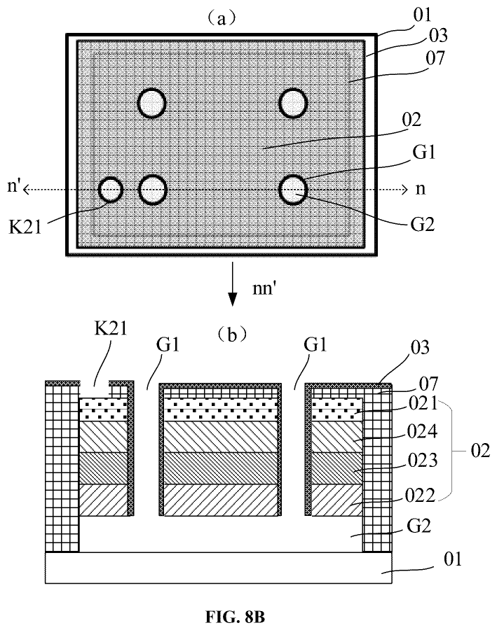

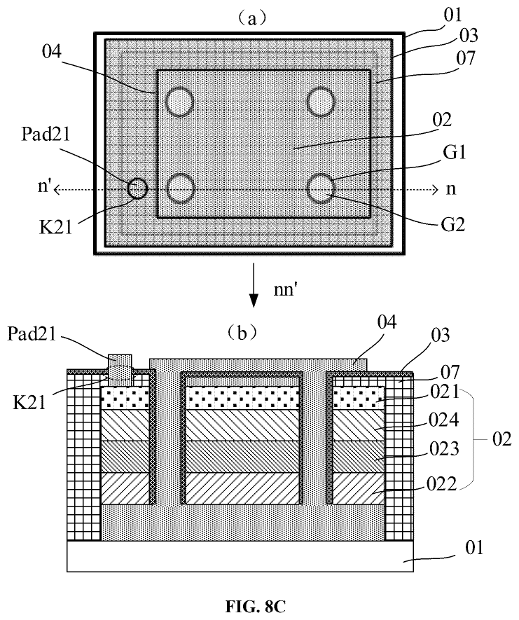

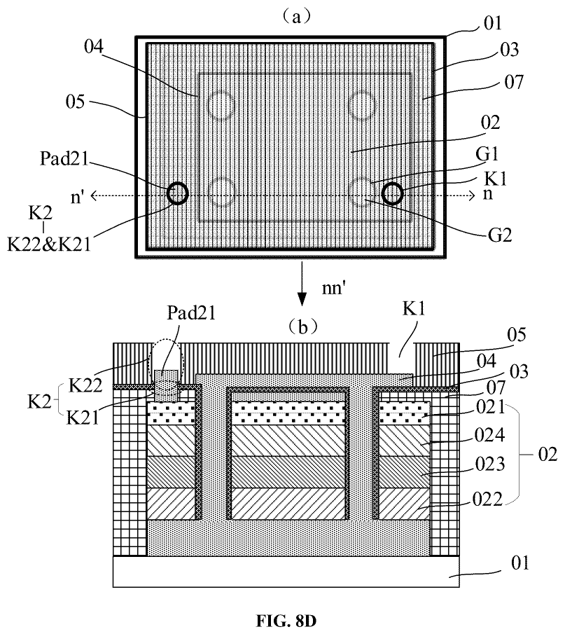

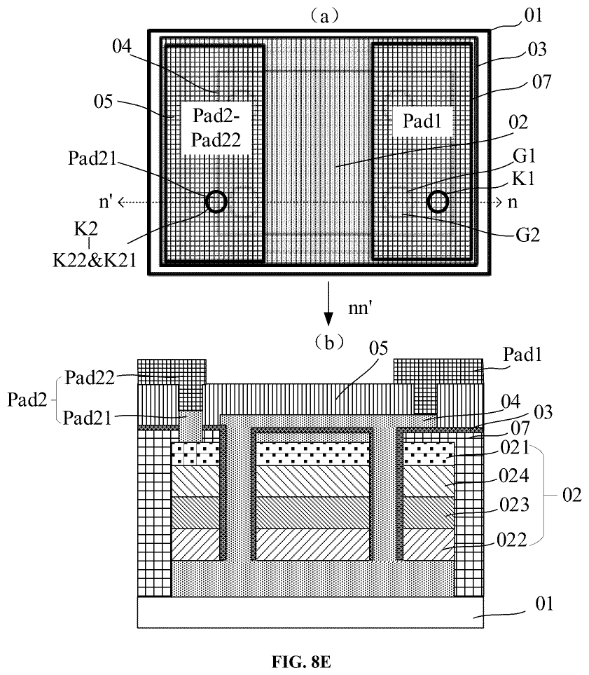

Exemplarily, FIG. 8A illustrates a schematic structural diagram of the formed first insulative layer 03 and first sub-via K21, including a top view a and a section view b.

In step C6, a second trench in communication with the at least one first trench is formed by removing all of the sacrificial layer.

Optionally, for the content of step C6, reference is made to step B6 described above, which is not repeated herein.

Exemplarily, FIG. 8B illustrates a schematic structural diagram of the formed second trench G2, including a top view a and a section view b.

In step C7, a conductive layer is formed and a conductive electrode is simultaneously formed.

Optionally, for the manner of forming the conductive layer, reference is made to step A7 described above, which is not repeated herein. For the manner of forming the conductive electrode, reference is made to step A9 described above, which is not repeated herein. That is, unlike the embodiments described above, in the embodiments, the conductive layer and the conductive electrode are formed simultaneously, and accordingly, the formed conductive layer and conductive electrode are disposed in the same layer as shown in FIG. 3.

Exemplarily, FIG. 8C illustrates a schematic structural diagram of the conductive layer 04 and conductive electrode Pad21 that are simultaneously formed, including a top view a and a section view b.

In step C8, a second insulative layer is formed on a side, away from the substrate, of the conductive layer.

Optionally, for the content of step C8, reference is made to step A10 described above, which is not repeated herein.

Exemplarily, FIG. 8D illustrates a schematic structural diagram of the formed second insulative layer 05, including a top view a and a section view b.

In step C9, a first sub-via running through the second insulative layer and exposing the electrically conductive layer is formed, and a second via including the first sub-via and a second sub-via is acquired by forming the second sub-via that runs through the second insulative layer and is in communication with the first sub-via.

Optionally, for the content of step C9, reference is made to step A11 described above, which is not repeated herein.

Exemplarily, referring to FIG. 8D, the formed first via K1 and the formed second sub-via K22 are shown.

In step C10, a first pad is formed on a side, away from the substrate, of the second insulative layer, and a second pad including a pad body and the conductive electrode is acquired by forming a pad body on the side, away from the substrate, of the second insulative layer.

Optionally, for the content of step C10, reference is made to step A12 described above, which is not repeated herein. Step C10 is referred to as a preparation step for the N-Pad and the P-Pad.

Exemplarily, FIG. 8E illustrates a schematic structural diagram of the formed first pad Pad1 and the formed pad body Pad22, including a top view a and a section view b.

(4) For the light-emitting unit shown in FIG. 4, the preparation method is as follows.

In step D1, a substrate is acquired.

Optionally, for the content of step D1, reference is made to step A1 described above, which is not repeated herein.

In step D2, a sacrificial film layer and an epitaxial film layer are successively formed on the substrate.

Optionally, for the content of step D2, reference is made to step A2 described above, which is not repeated herein.

In step D3, based on the shape of the light-emitting unit required to be formed, the sacrificial layer and the epitaxial layer that are successively stacked are formed by removing portions, close to an edge of the substrate, of the sacrificial film layer and the epitaxial film layer.

Optionally, for the content of step D3, reference is made to step A3 described above, which is not repeated herein.

In step D4, a support layer, and at least one first trench running successively through the support layer and the epitaxial layer and exposing the sacrificial layer are formed.

Optionally, for the content of step D4, reference is made to step B4 described above, which is not repeated herein.

In step D5, a first insulative layer is formed.

Optionally, for the content of step D5, reference is made to step A5 described above, which is not repeated herein.

In step D6, a second trench in communication with the at least one first trench is formed by removing all of the sacrificial layer.

Optionally, for the content of step D6, reference is made to step A6 described above, which is not repeated herein.

In step D7, a conductive layer is formed.

Optionally, for the content of step D7, reference is made to step A7 described above, which is not repeated herein.

In step D8, a second insulative layer is formed on a side, away from the substrate, of the conductive layer.

Optionally, for the content of step D8, reference is made to step A10 described above, which is not repeated herein.

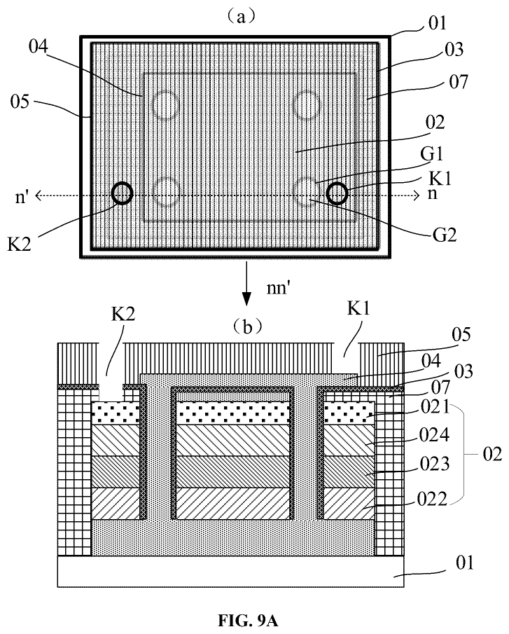

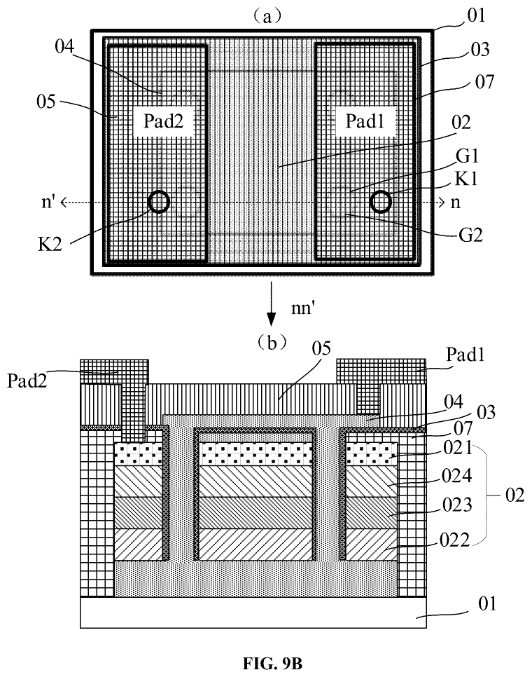

Exemplarily, FIG. 9A illustrates a schematic structural diagram of the formed second insulative layer 05, including a top view a and a section view b.

In step D9, a first via running through the second insulative layer and exposing the conductive layer, and a second via running successively through the second insulative layer and the first insulative layer and exposing the current spreading layer are formed.

Optionally, for the manner of forming the first via, reference is made to step A11 described above. In addition, in the embodiments, after the second insulative layer 05 is formed, the second via running through the second insulative layer and the first insulative layer and exposing the current spreading layer is formed at one time by etching the second insulative layer and the first insulative layer together. In some other embodiments, referring to the embodiments as described in (1) to (3), the second via K2 including the first sub-via K21 and the second sub-via K22 is acquired by forming the first sub-via K21 that runs through the first insulative layer 03 and the second sub-via K22 that runs through the second insulative layer 05 at different stages.

Exemplarily, referring to FIG. 9A, the formed first via K1 and the formed second via K2 are shown.

In step D10, a first pad and a second pad spaced that are apart from each other are formed on a side, away from the substrate, of the second insulative layer.

Exemplarily, FIG. 9B illustrates a schematic structural diagram of the formed first pad Pad1 and second pad Pad2, including a top view a and a section view b. Referring to FIG. 9B, in the embodiments, the second pad Pad2 is formed directly and the second pad Pad2 is electrically connected to the current spreading layer 021 through the second via K2 without forming the conductive electrode Pad21. That is, the formed first pad Pad1 is electrically connected to the conductive layer 04 through the first via K1, and the formed second pad Pad2 is electrically connected to the current spreading layer 021 through the second via K2. In this way, the preparation process is simplified and the cost is saved.

That is, for the embodiments described in (1) to (3) above, forming the second via K2 that runs successively through the second insulative layer 05 and the first insulative layer 03 and exposes the current spreading layer 021 includes the following.

First, prior to forming the second insulative layer 05, a first sub-via K21 running through the first insulative layer 03 and exposing the current spreading layer 021 is formed.

Then, after the second insulative layer 05 is formed, a second via K2 including the first sub-via K21 and a second sub-via K22 is acquired by forming the second sub-via K22 that runs through the second insulative layer 05 and is in communication with the first sub-via K21, Further, forming the second pad Pad2 on the side, away from the substrate 01, of the second insulative layer 05 includes the following.

First, prior to forming the second insulative layer 05, a conductive electrode Pad21 is formed within the first sub-via K21, and the formed conductive electrode Pad21 is electrically connected to the current spreading layer 021 through the first sub-via K21.

Then, after the second insulative layer 05 is formed, a pad body Pad22 is formed on the side, away from the substrate 01, of the second insulative layer 05, and the formed pad body Pad22 is electrically connected to the conductive electrode Pad21 through the second sub-via K22, such that the second pad Pad2 including the conductive electrode Pad21 and the pad body Pad22 is acquired.

For the embodiments shown in (4) above, as described in FIG. 5, the second via K2 that runs successively through the second insulative layer 05 and the first insulative layer 03 and exposes the current spreading layer 021 is formed directly, without distinguishing the first sub-via K21 and the second sub-via K22. Moreover, the second pad Pad2 is formed, and the second pad Pad2 is directly electrically connected to the current spreading layer 021 through the second via K2 without forming the conductive electrode Pad21.

Furthermore, in the scenario where the conductive electrode Pad21 is formed, for the embodiments documented in (1) and (2) above, forming the conductive electrode Pad21 within the first sub-via K21 includes: forming the conductive electrode Pad21 within the first sub-via K21 after the conductive layer 04 is formed. For the embodiments documented in (3) above, forming the conductive electrode Pad21 within the first sub-via K21 includes: forming the conductive electrode Pad21 disposed in the same layer as the conductive layer 04 within the first sub-via K21 at the same time as forming the conductive layer 04. In this way, the process is simplified and the cost is saved.

In summary, some embodiments of the present disclosure provide a light-emitting unit. The light-emitting unit includes the substrate, the epitaxial layer disposed on a side of the substrate, the first trench running through the epitaxial layer, the second trench disposed between the epitaxial layer and the substrate to expose the substrate, wherein the first trench and the second trench are in communication with each other, the first insulative layer disposed on the side, away from the substrate, of the epitaxial layer and covering the inner wall of the first trench, the conductive layer disposed on the side, away from the substrate, of the first insulative layer and extending through the first trench into the second trench, the second insulative layer disposed on the side, away from the substrate, of the conductive layer, and the first pad and the second pad that are respectively electrically connected to the conductive layer and the current spreading layer in the epitaxial layer by the vias running through the insulative layer. In this way, drive currents are reliably supplied by the first pad and the second pad respectively through the conductive layer and the current spreading layer for the two semiconductor layers that are stacked in the epitaxial layer, such that the light-emitting layer sandwiched between the two semiconductor layers reliably emits light. In this way, the drive current in the light-emitting unit flows vertically. Therefore, the prepared light-emitting unit has the advantages of uniform current distribution and better heat dissipation of the vertical LED, and also has the structure of the non-vertical LED, such that the ablation step of the substrate is eliminated, and thus the yield of the light-emitting unit is good.

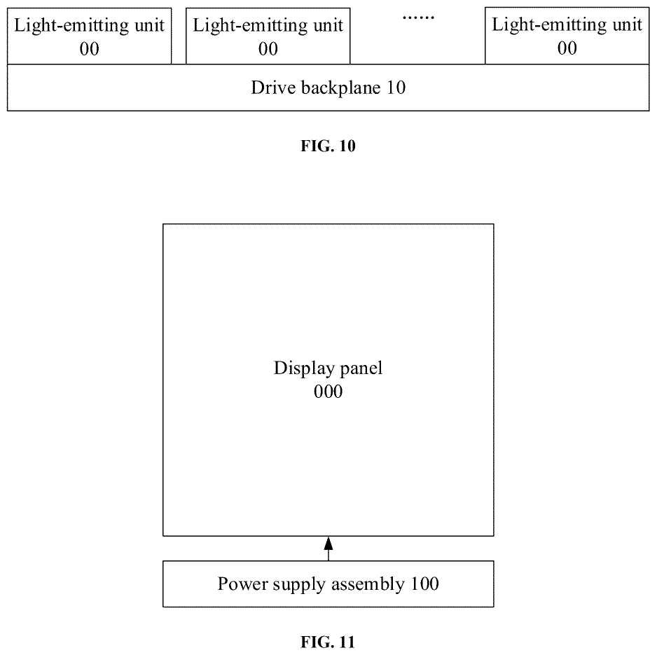

FIG. 10 is a schematic structural diagram of a display panel according to some embodiments of the present disclosure. As shown in FIG. 10, the display panel includes a drive backplane 10 and a plurality of light-emitting units 00 as shown in any one of FIG. 1 to FIG. 4.

The drive backplane 10 is coupled to the light-emitting units 00 and is configured to drive the light-emitting units 00 to emit light.

Because the display panel has substantially the same technical effects as the light-emitting units described in the previous embodiments, the technical effects of the display panel are not repeated herein for brevity.

FIG. 11 is a schematic structural diagram of a display device according to some embodiments of the present disclosure. As shown in FIG. 11, the display device includes a power supply assembly 100 and a display panel 000 as shown in FIG. 10.

The power supply assembly 100 is coupled to the display panel 000 and is configured to supply power to the display panel 000.

Because the display device has substantially the same technical effects as the light-emitting unit described in the previous embodiments, the technical effects of the display panel are not repeated herein for brevity.

It should be noted that the terms used in the detailed description of the present disclosure are merely for interpreting, instead of limiting, the embodiments of the present disclosure. It should be noted that unless otherwise defined, technical or scientific terms used in the embodiments of the present disclosure shall have ordinary meanings understandable by persons of ordinary skill in the art to which the disclosure belongs.

For example, the terms “first,” “second,” and the like used in the embodiments of the present disclosure are not intended to indicate any order, quantity, or importance, but are merely used to distinguish the different components.

Similarly, the terms such as “one” or “one” do not indicate a quantitative limitation, but rather the existence of at least one.

The terms “comprise,” “include,” and derivatives or variations thereof are used to indicate that the element or object preceding the terms covers the element or object following the terms and its equivalents, and shall not be understood as excluding other elements or objects.

The terms “on,” “under,” “left,” and “right” are only used to indicate the relative positional relationship. When the absolute position of the described object changes, the relative positional relationship may change accordingly. The terms “connect,” “couple,” and the like indicate an electrical connection.

The term “and/or” mentioned in the embodiments of the present disclosure indicates three relationships between contextual objects. For example, A and/or B may mean that A exists alone, A and B exist at the same time, and B exists alone. The symbol “/” generally denotes an “OR” relationship between contextual objects.

Described above are merely exemplary embodiments of the present disclosure, and are not intended to limit the present disclosure. Therefore, any modifications, equivalent substitutions, improvements, and the like made within the spirit and principles of the present disclosure shall be included in the protection scope of the present disclosure.

1. A light-emitting unit, comprising:
a substrate;
an epitaxial layer disposed on a side of the substrate, wherein the epitaxial layer comprises a current spreading layer;
at least one first trench and at least one second trench that are in communication with each other and expose the substrate, wherein the at least one first trench runs through the epitaxial layer, and the at least one second trench is disposed between the epitaxial layer and the substrate, an orthographic projection of the at least one second trench on the substrate being overlapped with an orthographic projection of the epitaxial layer on the substrate;
a first insulative layer disposed on a side, away from the substrate, of the epitaxial layer and covering an inner wall of the at least one first trench;
a conductive layer disposed on a side, away from the substrate, of the first insulative layer, wherein the conductive layer extends through the at least one first trench into the at least one second trench and is in contact with the substrate;
a second insulative layer disposed on a side, away from the substrate, of the conductive layer;
a first via running through the second insulative layer and exposing the conductive layer, and a second via successively running through the second insulative layer and the first insulative layer and exposing the current spreading layer; and
a first pad and a second pad that are disposed on a side, away from the substrate, of the second insulative layer and spaced apart from each other, wherein the first pad is electrically connected to the conductive layer through the first via, and the second pad is electrically connected to the current spreading layer through the second via.

2. The light-emitting unit according to claim 1, further comprising:
a sacrificial layer pattern disposed between the substrate and the epitaxial layer, wherein the sacrificial layer pattern has the at least one second trench exposing the substrate.

3. The light-emitting unit according to claim 1, further comprising: a support layer disposed on the side, away from the substrate, of the epitaxial layer and between the current spreading layer and the first insulative layer, wherein the support layer wraps around a sidewall, close to an edge of the substrate, of the epitaxial layer and is in contact with the substrate;
wherein the at least one first trench successively runs through the support layer and the epitaxial layer, and the first insulative layer is disposed on a side, away from the substrate, of the support layer and covers the inner wall of the at least one first trench.

4. The light-emitting unit according to claim 3, wherein a material of the support layer comprises an insulative material.

5. The light-emitting unit according to claim 1, wherein
the second via comprises a first sub-via and a second sub-via that are in communication with each other, the first sub-via running through the first insulative layer and exposing the current spreading layer, and the second sub-via running through the second insulative layer; and
the second pad comprises a conductive electrode and a pad body;
wherein the conductive electrode is disposed within the first sub-via and is electrically connected to the current spreading layer through the first sub-via; and the pad body is disposed on the side, away from the substrate, of the second insulative layer and is electrically connected to the conductive electrode through the second sub-via;
and wherein the conductive electrode and the conductive layer are disposed in a same layer.

6. (canceled)

7. The light-emitting unit according to claim 1, wherein the conductive layer comprises a first conductive block and a second conductive block; wherein
the first conductive block is filled within the at least one second trench; and
the second conductive block is disposed on the side, away from the substrate, of the first insulative layer, filled within the at least one first trench, and electrically connected to the first conductive block through the at least one first trench.

8. The light-emitting unit according to claim 1, wherein the light-emitting unit further satisfies any one of the following conditions:
the epitaxial layer comprises a first semiconductor layer, a light-emitting layer, and a second semiconductor layer that are disposed between the current-extending layer and the substrate and successively stacked along a direction away from the substrate;
the first pad comprises an N-type pad;
the second pad comprises a P-type pad;
the substrate comprises a sapphire substrate; and
the second insulative layer comprises a distributed Bragg reflector.

9. A method for preparing a light-emitting unit, applied to preparing the light-emitting unit as defined in claim 1, the method comprising:
acquiring a substrate;
successively forming a sacrificial layer and an epitaxial layer on the substrate, wherein the formed epitaxial layer comprises a current spreading layer;
forming at least one first trench running through the epitaxial layer and exposing the sacrificial layer;
forming a first insulative layer, wherein the formed first insulative layer is disposed on a side, away from the substrate, of the epitaxial layer and covers an inner wall of the at least one first trench;
forming at least one second trench that is in communication with the at least one first trench by removing at least a portion of the sacrificial layer, such that the substrate is exposed by the at least one first trench and the at least one second trench that are in communication with each other, wherein an orthographic projection of the formed at least one second trench on the substrate is overlapped with an orthographic projection of the epitaxial layer on the substrate;
forming a conductive layer, wherein the formed conductive layer is disposed on a side, away from the substrate, of the first insulative layer, extends through the at least one first trench into the at least one second trench, and is in contact with the substrate;
forming a second insulative layer on a side, away from the substrate, of the conductive layer;
forming a first via running through the second insulative layer and exposing the conductive layer and a second via successively running through the second insulative layer and the first insulative layer and exposing the current spreading layer; and
forming a first pad and a second pad that are spaced apart from each other on a side, away from the substrate, of the second insulative layer, wherein the formed first pad is electrically connected to the conductive layer through the first via, and the formed second pad is electrically connected to the current spreading layer through the second via.

10. The method according to claim 9, wherein forming the at least one second trench that is in communication with the at least one first trench by removing at least a portion of the sacrificial layer, comprises:
forming the at least one second trench that is in communication with the at least one first trench by removing a portion, disposed between the at least one first trench and the substrate, of the sacrificial layer.

11. The method according to claim 9, wherein prior to forming the first insulative layer, the method further comprises:
forming a support layer, wherein the formed support layer is disposed on the side, away from the substrate, of the epitaxial layer, wraps around sidewalls, close to an edge of the substrate, of the epitaxial layer and the sacrificial layer, and is in contact with the substrate;
wherein the formed at least one first trench successively runs through the support layer and the epitaxial layer and exposes the sacrificial layer, and the formed first insulative layer is disposed on a side, away from the substrate, of the support layer and covers the inner wall of the at least one first trench.

12. The method according to claim 11, wherein forming the at least one second trench that is in communication with the at least one first trench by removing at least a portion of the sacrificial layer comprises:
forming the at least one second trench that is in communication with the at least one first trench by removing all of the sacrificial layer.

13. The method according to claim 9, wherein removing at least a portion of the sacrificial layer comprises:
removing at least a portion of the sacrificial layer by etching the at least a portion of the sacrificial layer using an etching process.

14. The method according to claim 9, wherein
forming the second via successively running through the second insulative layer and the first insulative layer and exposing the current spreading layer comprises:
prior to forming the second insulative layer, forming a first sub-via running through the first insulative layer and exposing the current spreading layer; and
after forming the second insulative layer, acquiring the second via comprising the first sub-via and a second sub-via by forming the second sub-via running through the second insulative layer and in communication with the first sub-via; and
forming the second pad on the side, away from the substrate, of the second insulative layer comprises:
prior to forming the second insulative layer, forming a conductive electrode within the first sub-via, wherein the formed conductive electrode is electrically connected to the current spreading layer through the first sub-via; and
after forming the second insulative layer, acquiring the second pad comprising the conductive electrode and a pad body by forming the pad body on the side, away from the substrate, of the second insulative layer, wherein the formed pad body is electrically connected to the conductive electrode through the second sub-via.

15. The method according to claim 14, wherein forming the conductive electrode within the first sub-via comprises:
after forming the conductive layer, forming the conductive electrode within the first sub-via; or
at the same time as forming the conductive layer, forming the conductive electrode within the first sub-via, wherein the conductive electrode and the conductive layer are disposed in a same layer.

16. The method according to claim 9, wherein forming the at least one first trench running through the epitaxial layer and exposing the sacrificial layer comprises:
forming the at least one first trench running through the epitaxial layer and exposing the sacrificial layer by etching the epitaxial layer using an etching process;
wherein a number of the formed first trenches is positively related to a size of the light-emitting unit required to be formed, and a shape of each of the formed first trenches and arrangement of the formed first trenches match a shape of the light-emitting unit required to be formed.

17. The method according to claim 9, wherein forming the conductive layer comprises:
forming the conductive layer by filling a conductive material from the side, away from the substrate, of the first insulative layer toward within the at least one first trench and the at least one second trench;
wherein the conductive material comprises a transparent conductive material.

18. The method according to claim 9, wherein successively forming the sacrificial layer and the epitaxial layer on the substrate comprises:
successively forming a sacrificial film layer and an epitaxial film layer on the substrate, wherein the epitaxial film layer comprises a current spearing film layer, and a first semiconductor film layer, a light-emitting film layer, and a second semiconductor film layer that are disposed between the current spearing film layer and the substrate and are successively stacked along a direction away from the substrate; and
forming the sacrificial film layer and the epitaxial film layer that are successively stacked by removing portions, close to an edge of the substrate, of the sacrificial film layer and the epitaxial film layer based on a shape of the light-emitting unit required to be formed, wherein the epitaxial layer further comprises a first semiconductor layer, a light-emitting layer, and a second semiconductor layer that are disposed between the current spreading layer and the substrate and successively stacked along the direction away from the substrate.

19. The method according to claim 18, wherein successively forming the sacrificial film layer and epitaxial film layer on the substrate comprises:
growing the sacrificial film layer on the substrate; and
growing the epitaxial film layer on a side, away from the substrate, of the sacrificial film layer.

20. The method according to claim 18, wherein removing the portions, close to the edge of the substrate, of the sacrificial film layer and the epitaxial film layer comprises:
removing the portions, close to the edge of the substrate, of the sacrificial film layer and the epitaxial film layer by etching the portions, close to the edge of the substrate, of the sacrificial film layer and the epitaxial film layer using an etching process.

21. A display panel, comprising: a drive backplane, and a plurality of light-emitting units wherein
the driving backplane is coupled to the plurality of the light-emitting units and is configured to drive the plurality of light-emitting units to emit light; and
each of the plurality of light-emitting units comprises:
a substrate;
an epitaxial layer disposed on a side of the substrate, wherein the epitaxial layer comprises a current spreading layer;
at least one first trench and at least one second trench that are in communication with each other and expose the substrate, wherein the at least one first trench runs through the epitaxial layer, and the at least one second trench is disposed between the epitaxial layer and the substrate, an orthographic projection of the at least one second trench on the substrate being overlapped with an orthographic projection of the epitaxial layer on the substrate;
a first insulative layer disposed on a side, away from the substrate, of the epitaxial layer and covering an inner wall of the at least one first trench;
a conductive layer disposed on a side, away from the substrate, of the first insulative layer, wherein the conductive layer extends through the at least one first trench into the at least one second trench and is in contact with the substrate;
a second insulative layer disposed on a side, away from the substrate, of the conductive layer;
a first via running through the second insulative layer and exposing the conductive layer, and a second via successively running through the second insulative layer and the first insulative layer and exposing the current spreading layer; and
a first pad and a second pad that are disposed on a side, away from the substrate, of the second insulative layer and spaced apart from each other, wherein the first pad is electrically connected to the conductive layer through the first via, and the second pad is electrically connected to the current spreading layer through the second via.

22. (canceled)
